(19) United States
(12) Patent Application Publication
(10) Pub. No.: US 2026/0025142 A1
(43) Pub. Date: Jan. 22, 2026

(54) LINK MONITOR FOR UNRETIMED INTERFACES

(71) Applicant: Marvell Asia Pte Ltd, Singapore (SG)

(72) Inventors: Fernando De Bernardinis, Pavia (IT); Luca Vercesi, Pavia (IT)

(73) Assignee: Marvell Asia Pte Ltd, Singapore (SG)

(21) Appl. No.: 19/273,007

(22) Filed: Jul. 17, 2025

Related U.S. Application Data
(63) Continuation-in-part of application No. 19/272,032, filed on Jul. 17, 2025.
(60) Provisional application No. 63/672,795, filed on Jul. 18, 2024.
(60) Provisional application No. 63/673,212, filed on Jul. 19, 2024.

(51) Int. Cl. H03L 7/08; H03M 1/12

(52) U.S. Cl. CPC H03L 7/0807; H03M 1/12

(57) ABSTRACT

Linear unretimed interfaces lack clock and data recovery and retiming circuits implemented on a sophisticated digital signal processor. When the interface is not a retimed interface, it can be especially useful to extract some information about the link to allow for debugging and optimization of system deployment. An efficient solution can be implemented in unretimed interfaces to compute metrics such as the impulse response and signal histogram. Having the metrics allows for the solution to check and monitor the quality and the status of the link. Based on the link quality and status information, it is possible to address non-idealities and optimize performance of the unretimed interfaces and the link.

### PRIORITY APPLICATION

This patent application claims priority to and/or receives benefit from U.S. Provisional Application No. 63/672,795, titled, “Link Monitor for Unretimed Interfaces”, filed on Jul. 18, 2024, claims priority to and/or receives benefit from U.S. Provisional Application No. 63/673,212, titled, “SerDes Sampling Scope Mode”, filed on Jul. 19, 2024, and claims priority to and/or receives benefit from U.S. Non-Provisional application Ser. No. 19/272,032, titled, “SERDES SAMPLING SCOPE DEBUG MODE”, filed on Jul. 17, 2025. The U.S. Provisional applications and the U.S. Non-Provisional application are hereby incorporated by reference in their entirety.

### BACKGROUND

High-speed, high-bandwidth communication systems are integral to modern computing and networking applications. These systems are designed to facilitate efficient and reliable data transmission over various media or communication links, including optical fibers, copper cables, and wireless channels. Advances in communication technologies, such as signal modulation, error correction, and clock recovery, can ensure data integrity, reduce latency, and maintain synchronization across devices.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates data communications over an optical channel using retimed interfaces, according to some embodiments of the disclosure.

FIG. 2 illustrates data communications over an optical channel using one or more unretimed interfaces, according to some embodiments of the disclosure.

FIG. 3 illustrates an implementation of a link monitor in an unretimed interface processing a signal having pseudorandom sequence, according to some embodiments of the disclosure.

FIG. 4 illustrates an implementation of a link monitor in an unretimed interface processing a signal having a predetermined pseudorandom sequence with more than two signal levels, according to some embodiments of the disclosure.

FIG. 5 illustrates an implementation of a link monitor in an unretimed interface employing mission mode, according to some embodiments of the disclosure.

FIG. 6 illustrates an implementation of a link monitor in an unretimed interface processing a signal having a predetermined pseudorandom sequence with more than two signal levels and employing mission mode, according to some embodiments of the disclosure.

FIG. 7 illustrates an implementation of a link monitor to extract an oversampled impulse response, according to some embodiments of the disclosure.

FIG. 8 illustrates an implementation of a link monitor employing a single analog-to-digital converter (ADC) slice, according to some embodiments of the disclosure.

FIG. 9 illustrates an implementation of a link monitor employing a single ADC slice and processing a signal having a predetermined pseudorandom sequence with more than two signal levels, according to some embodiments of the disclosure.

FIG. 10 illustrates an implementation of a link monitor employing a single ADC slice and extracting an oversampled impulse response, according to some embodiments of the disclosure.

FIG. 11 illustrates an implementation of a link monitor employing a single ADC slice and applying decision feedback equalization, according to some embodiments of the disclosure.

FIG. 12 illustrates extracting conditional statistics based on detecting a particular sequence, according to some embodiments of the disclosure.

FIG. 13 illustrates extracting conditional statistics based on detecting a signal level condition, according to some embodiments of the disclosure.

FIG. 14 depicts a flow chart illustrating a method for link monitoring in an unretimed interface coupled to a communication link, according to some embodiments of the disclosure.

### DETAILED DESCRIPTION

### Overview

As artificial intelligence (AI) applications continue to evolve, they demand unprecedented data processing speeds and bandwidth capabilities to support their complex algorithms and massive datasets. Digital signal processors (DSPs), such as optical DSPs, can enable high-bandwidth optical interconnects for AI infrastructure. In particular, the DSPs can enable low-latency, high-performance, and energy-efficient data transfer. These DSPs can offer seamless connectivity across AI, cloud computing, enterprise systems, and 5G infrastructure. These DSPs offer sophisticated and complex clock and data recovery (CDR) circuits and retiming circuits on the transmit (TX) end of a communication link, receive (RX) end of the communication link, or both TX end and RX end of the communication link. Interfaces or module interfaces at the TX and/or RX ends of a communication link having a DSP implemented therein are referred to as retimed interfaces or retimed module interfaces. The DSPs can retransmit the signal by extracting the embedded clock and re-transmitting a clean, jitter-reduced, equalized, version of the data. Having these DSPs can significantly improve signal integrity, especially over long electrical traces or in systems with degraded signal quality. The benefits of the DSPs come at the cost of increased power consumption, added latency due to retiming circuits processing, and greater thermal complexity. Retimed interfaces are typically used in environments where signal fidelity is critical, and power budgets are more flexible.

In some scenarios, the communication distances are short. For example, data centers can have many intra-rack and short-reach connections, where signal integrity is easier to maintain. These connections are often found in 100G, 200G, and 400G applications for server-to-switch and switch-to-switch connections. In another example, high-performance computing for AI applications utilizes high-speed connections to connect compute nodes and these connections demand low-latency and high-bandwidth. In another example, 5G fronthaul networks connecting radio units and baseband processing have similar demands. In many modern computing scenarios, power consumption and heat generation are important concerns. For these scenarios, unretimed interfaces or unretimed module interfaces are gaining popularity. Unretimed interfaces do not include the DSPs of the retimed interfaces. By definition, unretimed interfaces do not include circuits for CDR and retiming circuits. Unretimed interfaces rely on the linearity of the analog signal components and signal paths to process and transmit a signal over the communication link or to receive and process a signal received over the communication link. Unretimed interfaces can include analog components like drivers and transimpedance amplifiers (TIAs). Relying on analog components and not using a power-hungry DSP means that unretimed interfaces consume significantly less power and introduce minimal latency. Examples of unretimed interfaces include linear pluggable optics (LPO) interfaces used at the TX end and/or the RX end of a communication link.

Linear unretimed interfaces lack CDR and retiming circuits implemented on a sophisticated DSP but offer benefits such as low power and low-latency. The lack of DSP in the unretimed interfaces presents a challenge. When the interface is not a retimed interface, it can be especially useful to extract some information about the link to allow for debugging and optimization of system deployment. However, because they do not implement a DSP, very little to no information is available to debug and optimize the communication link. The ability to monitor the performance of an unretimed interface, such as an arbitrary analog node in a serial link channel, can be beneficial for many reasons. For example, link status information can be used for performance tuning in a TX interface, such as nonlinear adaptation and optimization. In another example, link status information can be used for performance tuning in a RX interface, such as examining performance and linearity/non-linearity of the analog front end and/or the transimpedance amplifier.

Adding a link monitor to an unretimed interface for performance monitoring across the unretimed interface is not a trivial task. The link monitor preferably is designed to extract useful metrics about the communication link while not incurring the costs and complexities associated with the DSPs found in retimed interfaces. Phrased differently, the link monitor observing an arbitrary analog node preferably utilizes minimal hardware. To address this technical task, an efficient solution can be implemented in unretimed interfaces to compute metrics such as the impulse response and signal histogram. Having the metrics allows for the solution to check and monitor the quality and the status of the link. The metrics can offer telemetry of the communication link, allow for debugging of the link, and be used to drive the optimization of the link performance. Based on the link quality and status information, it is possible to address non-idealities and optimize or tune the performance of the unretimed interfaces and the link.

In some embodiments, the efficient link monitor can be implemented on a lightweight application-specific integrated circuit (ASIC) or a lightweight processing circuit or mixed-signal processor to offer monitoring features that does not interfere or impact the low-latency data path offered by the unretimed interface. More specifically, the link monitor does not perform CDR or retiming of the signal being passed through the low-latency data path of the unretimed interface. Rather, the link monitor passively senses, observes, and monitors the signal being passed through the low-latency data path to extract link status information.

In some embodiments, the efficient link monitor implements a subset of slices of a time-interleaved ADC to sample an analog signal at an arbitrary analog node in the unretimed interface. Utilizing just a subset of slices significantly reduces the footprint of the link monitor. A minimal clock recovery circuit can be implemented for the subset of slices sampling the signal to ensure proper sampling timing. The digital samples produced by the subset of slices can be used to produce a signal histogram and/or an impulse response. The signal histogram and/or impulse response can be used to extract metrics about the communication link.

In some embodiments, the link monitor can include one or more ADC slices to receive an analog signal in the unretimed interface coupled to a communication medium of a communication link and output one or more digital samples of the analog signal corresponding to one or more phases. The link monitor can further include one or more slicers downstream of corresponding one or more ADC slices to output one or more determined symbols based on the one or more digital samples produced by the one or more ADC slices. The link monitor further includes a minimal clock recovery circuit to receive the one or more determined symbols and output a frequency control word to a phase locked loop (PLL). The link monitor further includes the phase locked loop to output a clock signal to clock the one or more ADC slices based on the frequency control word. The link monitor can include a link metrics extraction circuit to output one or more metrics of the communication link based on the one or more digital samples of the analog signal produced by the one or more ADC slices.

In some embodiments, the link metrics extraction circuit includes a signal monitor circuit to generate a signal histogram based on the one or more digital samples of the analog signal produced by the one or more ADC slices.

In some embodiments, the link metrics extraction circuit includes an impulse response circuit to generate an impulse response of the link based on the one or more digital samples of the analog signal produced by the one or more ADC slices and one or more expected digital samples of the analog signal. In some embodiments, a predetermined sequence or signal (e.g., a sequence or signal produced using a known function, and/or the signal has a predetermined pattern) is being processed by the unretimed interface, and the one or more expected digital samples of the analog signal can be reconstructed or generated using a pseudorandom sequence generator.

In some embodiments, the one or more ADC slices comprise an ADC slice having a programmable phase. The ADC slice having the programmable phase can operate in a mission mode to obtain digital samples at various time instances, phases, or unit intervals (UIs). The one or more phases of the digital samples produced by the one or more ADC slices can correspond to a plurality of phases, such as a plurality of UIs or range of consecutive time instances. The digital samples produced by the ADC slice with the programmable phase can be cross correlated with one or more determined symbol output by a slicer of the one or more slicers to obtain the impulse response. Including the ADC slice having the programmable phase to operate in mission mode allows for the impulse response to be extracted without having to pass through a predetermined sequence or signal (e.g., a pseudorandom sequence).

In some embodiments, the link monitor is compatible with modulation schemes that utilize more than two signal levels, such as Pulse Amplitude Modulation with 4 levels (PAM4). The link monitor can further include a programmable gain stage to adjust the signal levels of the one or more digital samples produced by the one or more ADC slices to produce one or more adjusted digital samples. The link monitor can include a least means square (LMS) circuit that controls the programmable gain stage based on the one or more adjusted digital samples and one or more determined symbols produced by the one or more slicers. The slicers can operate with multiple thresholds, depending on the modulation scheme.

In some embodiments, the clock recovery circuit uses a timing error detection algorithm that computes timing errors based on determined symbols corresponding to three consecutive phases, time instances, or UIs. Accordingly, the subset of slices of the time-interleaved ADC can include just three ADC slices and other slices can be omitted. In some cases, there can be 64 or 128 ADC slices in a full time-interleaved ADC operating at Baud Rate (BR) of the interface. The BR of an interface refers to the number of symbol changes or signaling events per second, representing the rate at which data is transmitted over the communication link. To include only three ADC slices means that the footprint of the link monitor is significantly reduced.

In some embodiments, the clock recovery circuit uses a timing error detection algorithm that computes timing errors based on determined symbols corresponding to two consecutive phases, time instances, or UIs. Accordingly, the subset of slices of the time-interleaved ADC can include just two ADC slices and other slices can be omitted. To include only two ADC slices means that the footprint of the link monitor is significantly reduced.

In some embodiments, the clock recovery circuit uses a timing error detection algorithm that computes timing errors based on determined symbols corresponding to three consecutive phases, time instances, or UIs. When a predetermined sequence or signal is being processed by the unretimed interface, the two determined symbols of the three determined symbols can be derived from one of the determined symbols using a pseudorandom sequence generator. Accordingly, the subset of slices of the time-interleaved ADC can include just one ADC slice and other slices can be omitted. To include only one ADC slice means that the footprint of the link monitor is significantly reduced.

In some embodiments, the clock recovery circuit may operate to downsample timing errors associated with one or more ADC slices to achieve fractional locking of the clock signal at the BR. When the summing circuitry is configured to perform downsampling of timing errors at a specific downsampling rate, or if the timing errors are produced at a downsampled or subsampled rate, the clock recovery circuit can achieve fractional lock and produce a clock signal having a clock frequency at a rational fraction of the BR of the communication link. The rate can be a rate of 1 out of P. If P is large enough (e.g., 32, 64, or 128), it is possible to achieve stable operating points near BR, such that the clock recovery circuit locks on to a clock frequency is near BR, such as

$$\frac{P + 1}{P} * BR and \frac{P - 1}{P} * BR .$$

When the one or more ADC slices are clocked at the rational fraction of the BR, the one or more ADC slices can operate in sampling scope mode, and the one or more phases of the one or more digital samples can correspond to fractional phases within a unit interval. The digital samples with fractional phases within a unit interval and one or more expected digital samples can be used to produce an oversampled impulse response. The one or more expected digital samples can be generated by a pseudorandom sequence generator according to a predetermined periodic signal being sampled at the rational fraction of BD. Details relating to sampling scope mode, such as downsampling and selection of timing errors to achieve fractional lock to obtain an oversampled response, are discussed in U.S. Non-Provisional application Ser. No. 19/272,032, titled, “SERDES SAMPLING SCOPE DEBUG MODE”, filed on Jul. 17, 2025, which is hereby incorporated by reference in its entirety.

In some embodiments, the minimal implementation of the link monitor involving just one ADC slice can be augmented to include decision feedback equalization (DFE) with a simple LMS circuit to improve the locking abilities of the clock recovery circuit. The pseudorandom sequence generator can produce a previous expected digital sample, and the LMS circuit can implement a feedback loop based on an error signal and generate one or more filter coefficients that can minimize the error signal. The DFE circuit can apply the one or more filter coefficients to the previous expected digital sample and output a correction signal. The correction signal can be applied to a signal upstream of a slicer.

In some embodiments, the metrics can be conditioned on one or more signal conditions. The link metrics extraction circuit can be triggered based on detection of the one or more signal conditions. For example, a signal condition can include detecting a specific subsequence within the predetermined sequence. In another example, a signal condition can include detecting that the signal meets a signal level condition or range. The metrics can reveal information about the communication link under different conditions or scenarios to assist with debugging and performance tuning.

While various examples refer to communication links involving an optical or fiber optical channel where the communication medium is fiber or optical fiber, it is envisioned by the disclosure that various embodiments are applicable to communication links with other types of communication media demanding low-latency, low power and efficient interfaces. Other types of communication media can include metal conductor wires or cables, wired links, wireless links, over the air communications, radio frequency communications, millimeter wave communications, satellite communications, etc.

While the link monitor may include circuit components that can be found in the DSP of retimed interfaces, the link monitor and the circuit components therein are patentably distinct from those of the DSP for several reasons. For instance, only a subset of N ADC slices is provided as opposed to all N ADC slices of a full time-interleaved ADC. In addition, fewer slicers are provided to determine the symbols. In another instance, the clock recovery circuitry in the link monitor is simplified in comparison to the CDR and retiming circuits of the DSP. In another instance, a complex equalizer can be omitted in the link monitor in some embodiments. In another instance, the link monitor represents an observation path that does not modify the signal propagating through the unretimed interface and serves to extract metrics and link status information. In contrast, the CDR and retiming circuits in the DSP are used to directly modify and augment the signal propagating through the retimed interface.

Contrasting retimed interfaces and unretimed interfaces with a lightweight link monitor

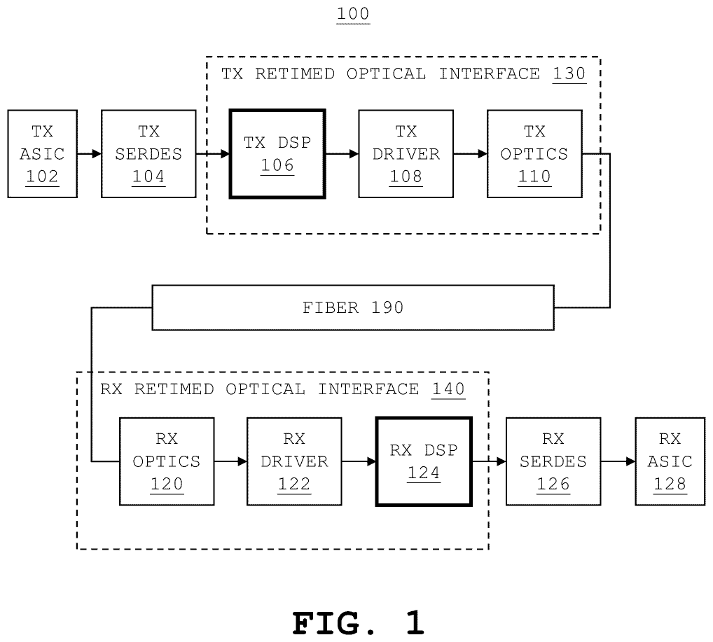

FIG. 1 illustrates data communications over an optical channel using retimed interfaces, according to some embodiments of the disclosure. Communication link 100 includes TX ASIC 102, TX Serializer-Deserializer (SerDes) 104, TX retimed optical interface 130, fiber 190 as the communication medium, RX retimed optical interface 140, RX SerDes 126, and RX ASIC 128.

TX ASIC 102 may generate data to be transmitted. TX ASIC 102 is communicably coupled to TX SerDes 104, and the data being generated by TX ASIC 102 can be serialized for transmission by TX SerDes 104. TX SerDes 104 interfaces with TX retimed optical interface 130 where the serialized data may undergo processing by TX retimed optical interface 130.

In TX retimed optical interface 130, TX DSP 106 can perform advanced digital signal processing algorithms to condition the outgoing data stream, such as CDR and retiming. The output of TX DSP 106 is provided to TX driver 108, which amplifies and conditions the electrical signal for optical conversion. TX optics 110 of TX retimed optical interface 130 can perform electrical-to-optical conversion for data transmission over fiber 190. TX optics 110 can include optics circuitry coupled to fiber 190. TX optics 110 can include a laser that is driven by the amplified signal produced by TX driver 108. TX optics 110 thus transmits the data optically over fiber 190 from the TX end of communication link 100.

At the RX end of communication link 100, the optical signal can be received by retimed optical interface 140, in particular, RX optics 120. RX optics 120 can convert the incoming optical signal from fiber 190 back into the electrical domain. RX optics 120 can include optics circuitry coupled to fiber 190. RX optics 120 can include a photodiode. The electrical signal produced by RX optics 120 can be conditioned by RX driver 122 of retimed optical interface 140 prior to further signal processing. The conditioned electrical signal produced by RX driver 122 can be processed by RX DSP 124, which can apply various equalization and error correction techniques to recover the transmitted data with high fidelity.

The processed data from RX DSP 124 is passed to RX SerDes 126, which can performs serial-to-parallel conversion, or deserialization and presents the recovered deserialized data to RX ASIC for subsequent processing or application-specific handling.

Notably, TX DSP 106 and RX DSP 124 include circuits that perform CDR and retiming of the signal being propagated, transmitted, or received over communication link 100. While TX retimed optical interface 130 and retimed optical interface 140 facilitate robust CDR by retiming transmitted and received signals, thereby directly compensating for channel impairments and timing uncertainties induced during transmission over fiber 190, TX DSP 106 and RX DSP 124 add significant power consumption, complexity, cost, and latency to communication link 100 within TX retimed optical interface 130 and retimed optical interface 140.

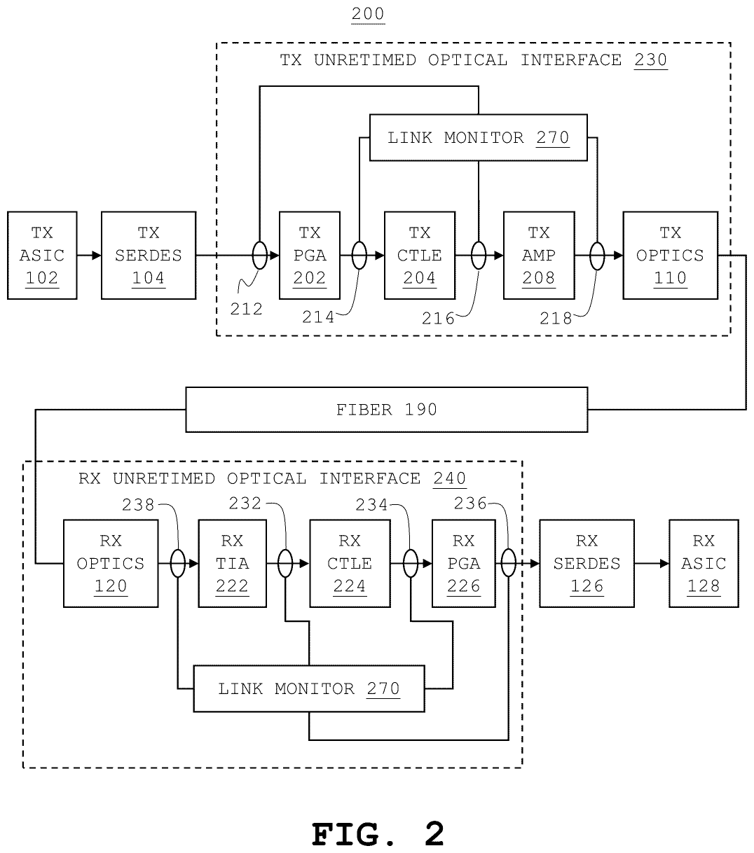

FIG. 2 illustrates data communications over an optical channel using one or more unretimed interfaces, according to some embodiments of the disclosure. Communication link 200 includes TX ASIC 102, TX SerDes 104, TX unretimed optical interface 230, fiber 190, RX unretimed optical interface 240, RX SerDes 126, and RX ASIC 128. In some cases, an unretimed interface is implemented on just the TX end of communication link 200, just the RX end of communication link 200, or both the TX end and the RX end of communication link 200.

TX unretimed optical interface 230 differs from TX retimed optical interface 130 in that there is no sophisticated DSP (e.g., TX DSP 106). Rather, TX unretimed optical interface 230 relies on one or more analog circuits coupled to TX optics 110 to process and condition the signal to be sent over fiber 190. In some implementations, the one or more analog circuits in the analog signal chain of TX unretimed optical interface 230 can include TX programmable gain amplifier (PGA) 202, TX continuous-time linear equalizer (CTLE) 204, and TX amplifier 208. These active analog circuits can be sequentially coupled in the signal path, each performing distinct yet interrelated signal conditioning functions prior to optical modulation by TX optics 110. The absence of a DSP in TX unretimed optical interface 230 places greater design emphasis on the precision, linearity, and adaptability of these analog circuits.

TX PGA 202 can serve as an initial active amplification stage following TX SerDes 104. TX PGA 202 can provide adjustable signal gain to accommodate variations in upstream signal amplitude, process variations, and to optimize signal swing for the subsequent equalization and amplification stages (e.g., TX CTLE 204 and TX amplifier 208). TX PGA 202 can include a differential amplifier circuit structure, such as a variable transconductance stage or cascaded operational amplifiers configured with digitally- or analog-controlled resistor networks. Gain programmability may be achieved through switched resistor ladders, variable resistors, or current-steering architectures. TX PGA 202 implementing selectable or continuously variable gain can normalize the input signal magnitude, compensate for channel loss or attenuation, and facilitate dynamic range optimization.

TX CTLE 204 can perform pre-emphasis or frequency-shaped equalization of the electrical signal, compensating for deterministic channel loss, particularly high-frequency attenuation incurred as the signal traverses printed circuit board traces, connectors, and TX optics 110. TX CTLE 204 can include a differential amplifier stage with a frequency-dependent feedback and/or feedforward network. This network often includes parallel resistor-capacitor (RC) or Resistor-Inductor-Capacitor (RLC) elements that form one or more zero-pole pairs, shaping the amplifier transfer function. Programmability can be achieved via switchable capacitor or resistor banks, controlled by digital signals or analog control voltages. TX CTLE 204 can apply controlled gain at higher frequencies relative to lower frequencies to counteract the roll-off introduced by channel losses. This pre-emphasis functionality can boosts the high-frequency content, improving waveform integrity and reducing inter-symbol interference at the receiver. TX CTLE 204 can be designed to avoid excessive peaking, which could introduce noise amplification or unwanted ringing.

TX amplifier 208 can function as a final driver stage within the electrical domain before TX optics 110. TX amplifier 208 can generate the requisite signal amplitude and drive capability to effectively modulate the optical transmitter (e.g., a laser diode) in fiber 190 with minimal distortion and high fidelity. TX amplifier 208 can include a high-linearity, wide-bandwidth differential driver, such as a current-mode logic (CML) driver or source-degenerated differential pair, capable of delivering sufficient output swing and current to the optical modulator. The design may incorporate impedance matching networks for optimal energy transfer and reflection minimization. TX amplifier 208 can ensure that the processed and equalized signal attains the appropriate voltage and/or current levels demanded by the downstream optical elements, such as the laser's modulation input in fiber 190. Preferably, TX amplifier 208 maintains high-linearity to prevent signal compression and harmonic distortion, possesses sufficient slew rate to preserve high-speed transitions, and exhibits robust common-mode rejection to minimize crosstalk and extraneous noise coupling.

RX unretimed optical interface 240 differs from RX retimed optical interface 140 in that there is no sophisticated DSP (e.g., RX DSP 124). Rather, RX unretimed optical interface 240 relies on one or more analog circuits coupled to RX optics 120 to process and condition the signal received over fiber 190. In some implementations, the one or more analog circuits in the analog signal chain of RX unretimed optical interface 240 can include RX transimpedance amplifier (TIA) 222, RX CTLE 224, and RX PGA 226. These active analog circuits can be sequentially coupled in the signal path, each performing distinct yet interrelated signal conditioning functions after receiving a signal over 110 by RX optics 120. For RX unretimed optical interface 240, signal integrity and conditioning performed at the RX end can be important in the absence of a sophisticated DSP.

RX TIA 222 serves as an interface between the photodetector (such as a photodiode) in RX optics 120 and the downstream electrical circuitry on in RX unretimed optical interface 240. RX TIA 222 can convert the current output of the photodetector, which responds to incoming optical power, into a voltage signal with sufficient amplitude and fidelity for subsequent processing. RX TIA 222 can include a high-gain, low-noise operational amplifier topology, optionally augmented with feedback networks to set the desired transimpedance gain and bandwidth. Programmability may be implemented using selectable resistor banks or digitally controlled feedback elements, enabling adaptation to varying optical power levels and photodiode characteristics. RX TIA 222 can minimize input-referred noise and maximize linearity, thereby preserving the signal-to-noise ratio (SNR) and ensuring reliable data transmission even at high data rates or under suboptimal optical conditions.

RX CTLE 224 can include an analog filter in RX unretimed optical interface 240, tasked with compensating for frequency-dependent losses induced by the channel, package, printed circuit board traces, and RX optics 120. RX CTLE 224 can include a differential amplifier stage equipped with frequency-selective networks, such as parallel RC or RLC elements, to shape the frequency response of the incoming signal. By providing greater gain at higher frequencies relative to lower frequencies, RX CTLE 224 can mitigate the effects of high-frequency attenuation. Programmability may be realized through switchable capacitor and resistor arrays, controlled by configuration registers or adaptive bias networks, allowing the equalizer response to be tuned to the specific channel characteristics or to accommodate different link environments. The design of RX CTLE 224 can balance adequate high-frequency boost against the risk of introducing peaking artifacts or excessive noise amplification, thereby preserving both the timing and amplitude integrity of the recovered signal.

RX PGA 226 can include a variable amplification stage to further adapt the conditioned signal for optimal processing by the downstream RX SerDes 126 or other circuits. RX PGA 226 may include circuits involving a differential amplifier topology, such as a variable transconductance amplifier or a cascaded operational amplifier arrangement with digitally or analog-controlled gain elements. The gain programmability feature can be implemented via resistor ladders, switched-capacitor banks, or current-steering techniques to allow for adjustment in response to fluctuating signal amplitudes, process variations, and varying channel losses. RX PGA 226 can perform normalization of the signal swing, maximization of the available dynamic range, and improvement in signal fidelity prior to serialization or deserialization. RX PGA 226 can be designed for high-linearity, low distortion, and strong common-mode rejection to ensure that amplitude errors, crosstalk, and extraneous noise sources do not degrade the quality of the received data stream.

For an unretimed interface such as TX unretimed optical interface 230 and RX unretimed optical interface 240, the one or more analog circuits can include an amplifier, a TIA, a transconductance amplifier, a PGA, an equalizer, a CTLE, etc. It can be beneficial to be able to extract quantitative metrics about communication link 200 using minimal hardware. To extract the metrics, link monitor 270 can be implemented in TX unretimed optical interface 230 and/or RX unretimed optical interface 240 to sense a signal at an observation point, e.g., an analog node in the signal chain formed by the one or more analog circuits. An observation point can be an input to an analog circuit, or an output of the analog circuit. Possible observation points in TX unretimed optical interface 230 can include node 212, node 214, node 216, and node 218. Possible observation points in RX unretimed optical interface 240 can include node 238, node 232, node 234, and node 236. Link monitor 270 can be coupled to receive, sense, observe, and/or monitor an analog signal at an observation point, and extract and output one or more metrics about communication link 200.

### Various Implementations of the Link Monitor

Obtaining one or more metrics about a communication link, such as generating a signal histogram, a BR impulse response, and/or an oversampled impulse response can offer deep insight into the communication link. The signal histogram and impulse response can complement each other to offer a full picture of the link status. Moreover, the metrics can be conditioned on one or more conditions such as signal level, data level, and certain data sequences to offer more specific information about the link status under different conditions. Examples of metrics that can be extracted from the signal histogram can include an average value or level (or mean), variance, standard deviation, skewness or asymmetry of distribution, kurtosis, higher-order moments, peak-to-average power ratio, crest factor, dynamic range, SNR, probability density function characteristics, cumulative distribution function characteristics, peak signal levels, minimum signal levels, median signal level, percentile values, interquartile range, signal clipping indicators, histogram entropy, effective number of bits (ENOB), spurious-free dynamic range (SFDR), total harmonic distortion (THD) indicators, amplitude distribution uniformity, etc. Examples of metrics that can be extracted from the impulse response can include rise time and fall time, setting time, overshoot and undershoot, delay spread, coherence time, peak amplitude and time location, bandwidth, group delay and group delay variation, phase response linearity, frequency response flatness, stopband attenuation, passband ripple, signal-to-interference ratio (SIR), channel capacity estimates, bit error rate (BER) predictions, eye diagram metrics, inter-symbol interference (ISI) characteristics, derived equalization requirements, derived matched filter performance, derived channel estimation accuracy, derived synchronization metrics, etc.

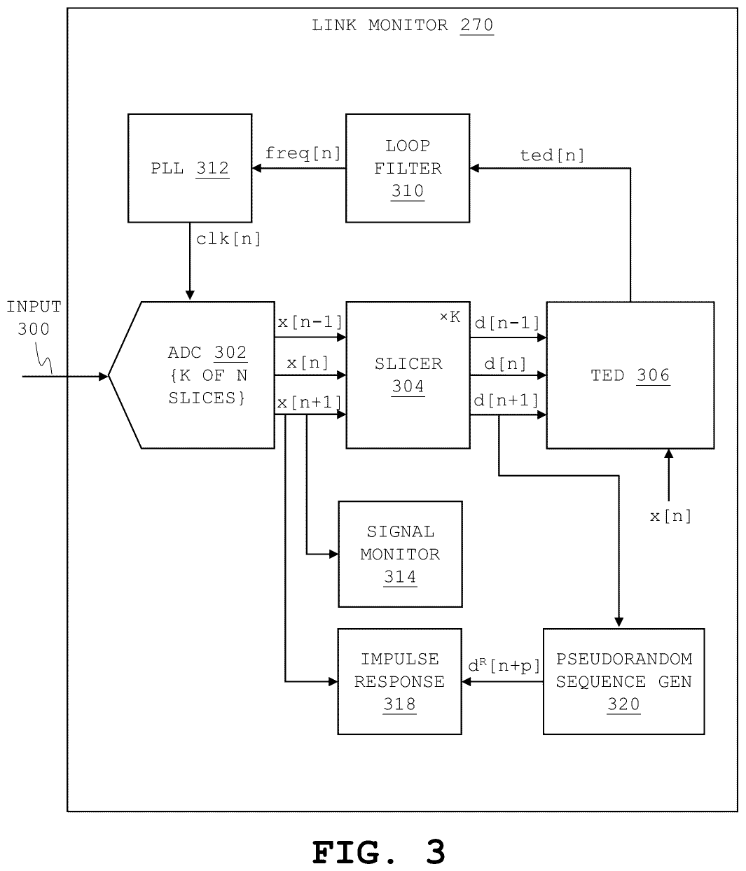

To extract the one or more metrics out of a modulated signal transmitted at BR can involve locking to the modulated signal being propagated over the communication link. Locking to the modulated signal can be achieved by implementing a clock recovery circuit and a phase locked loop controlled by the clock recovery circuit. FIGS. 3-11 illustrate minimal hardware that can sample the modulated signal properly to extract the one or more metrics. To design an efficient link monitor, basic demands for sampling and locking to the modulated signal include implementing an ADC to sample an input signal, an equalizer, a slicer to extract the transmitted symbol, a timing error detector (TED) to extract timing information since two clocks are not the same, a loop filter to minimize a timing error, and a numerically controlled oscillator (NCO) driven by the loop filter to produce a clock signal to drive the ADC. For example, the NCO can include a phased locked loop that is controlled by a frequency control word produced by the loop filter.

BR is typically quite high, thus the ADC used to sample the input signal can be a time-interleaved ADC having N parallel ADC slices (or N parallel ADC channels), each triggered to sample and hold the input signal one after another at different phases (e.g., at a specific phase offset) to collectively achieve an effective sampling rate that is equal to or greater than BR. In some implementations of a time-interleaved ADC, the input signal can fan out to parallel sample and hold circuits and ADC circuitry to perform analog-to-digital conversion of the signal held in the sample and hold circuits. The ADC circuitry in an ADC slice can employ one or more ADC architectures, such as successive approximation register (SAR) ADCs, pipelined ADCs, flash ADCs, voltage-to-time conversion assisted SAR ADCs, delta-sigma ADCs or oversampled ADCs, etc. In some embodiments, N=64. In some embodiments, N=128.

Recognizing that TED algorithms implemented in the TED may use a just small number of consecutive samples, the implementation of the high-speed ADC to sample the input signal can be greatly simplified. For example, a Zero Forcing (ZF) TED algorithm may use three consecutive samples of the input signal. In another example, a different TED algorithm may use two consecutive samples of the input signal. This means that for the clock recovery circuit to operate properly to perform locking, the clock recovery circuit only needs a subset of digital samples of the input signal and can still be able to lock onto the modulated signal. Consequently, a small subset of the N ADC slices, such as K of N ADC slices can be implemented as a simplified ADC in the efficient link monitor. In one implementation, K=3 of N ADC slices (N-K other slices are omitted) can be provided in the link monitor for a TED that employs three consecutive samples. In one implementation, K=2 of N ADC slices (N-K other slices are omitted) can be provided in the link monitor for a TED that employs two consecutive samples. Significant reduction of ADC slices translates to significant savings in power and area for the efficient link monitor.

When the data being transmitted involves non-return-to-zero (NRZ) data, or data encoded or modulated using the NRZ scheme, the need to include an equalizer is obviated because the target channel can have moderate insertion loss (e.g., <15 dB). NRZ data, or binary data, is represented using two distinct voltage levels corresponding to logical ‘0’ and logical ‘1’. A bit can be transmitted as a constant voltage level over a fixed time interval (referred to herein as a unit interval separating consecutive symbols), without returning to a baseline or neutral level between bits. Dealing with NRZ data can mean that the equalizer is not needed. Consequently, the efficient link monitor does not need to implement an equalizer.

When a known or predetermined sequence or signal is being transmitted, such as pseudorandom sequence data or pseudorandom binary sequence (PRBS) data, a sequence generator can be used to produce expected digital samples. An impulse response can be produced by cross-correlating the digital samples produced by the ADC and the expected digital samples. The cross-correlation operation can be implemented efficiently in hardware in the link monitor.

FIG. 3 illustrates an implementation of link monitor 270 in an unretimed interface processing a signal having pseudorandom sequence (e.g., PRBS signal), according to some embodiments of the disclosure. The unretimed interface is coupled to a communication medium of a communication link. In particular, the implementation of link monitor 270 illustrated in FIG. 3 can be used to observe a signal carrying NRZ data, specifically, PRBS data.

Link monitor 270 includes one or more ADC slices 302, such as K of N slices, to sample input 300. For example, K=3. In another example K=2. In the illustration, one or more ADC slices 302 can receive an analog signal (e.g., input 300 at one of the observation points illustrated in FIG. 2). One or more ADC slices 302 can output one or more digital samples of the analog signal corresponding to one or more phases. For example, three ADC slices in one or more ADC slices 302 produce three digital samples, x[n−1], x[n], and x[n+1] respectively, at three different phases, time instances, or UIs. The three digital samples are separated by one unit interval. In another example, two ADC slices in one or more ADC slices 302 produce two digital samples, x[n−1] and x[n] respectively, or x[n] and x[n+1] respectively, at two different phases, time instances, or UIs.

Link monitor 270 includes one or more slicers 304 to output one or more determined symbols based on the one or more digital samples produced by one or more ADC slices 302. For example, link monitor 270 may include K parallel slicers for K ADC slices. When K=3, the three slicers in one or more slicers 304 produce three determined symbols, d[n−1], d[n], and d[n+1], based on three digital samples, x[n−1], x[n], and x[n+1] respectively. When K=2, the two slicers in one or more slicers 304 produce two determined symbols, d[n−1] and d[n], or d[n] and d[n+1], based on two digital samples, x[n−1] and x[n] respectively, or x[n] and x[n+1] respectively. When processing NRZ data, a slicer in one or more slicers 304 can determine the determined symbol through a sign operation to obtain d[n] from x[n]. A digital sample, x, produced by an ADC slice in one or more ADC slices 302 is provided to a corresponding slicer in one or more slicers 304 to determine a determined symbol, d.

Link monitor 270 includes a clock recovery circuit, which can include TED 306 and loop filter 310. The clock recovery circuit can receive the one or more determined symbols (e.g., d[n−1], d[n], and d[n+1]), and output a frequency control word, freq[n] to PLL 312. TED 306 may receive the one or more determined symbols, d[n−1], d[n], and d[n+1], and a digital sample, x[n], and determines a timing error, ted[n]. In some implementations, TED 306 can implement ZF TED, which calculates the following as the timing error: ted[n]=(d[n]−x[n])*(d[n+1]−d[n−1]). ZF TED utilizes three determined symbols of three digital samples corresponding to three consecutive phases (e.g., d[n−1], d[n], and d[n+1]) to calculate the timing error, ted[n]. The timing error, ted[n], can be provided to loop filter 310, which operates to produce the frequency control word, freq[n], to reduce or drive the timing error, ted[n], to zero. At lock or a stable operating point of the clock recovery circuit, E [TED]=0=−E [x[n] *(d[n+1]-d[n−1])] because the data becomes uncorrelated. In some embodiments, TED 306 can implement a TED algorithm that uses two determined symbols, e.g., d[n−1] and d[n], or d[n] and d[n+1], and the digital sample, e.g., x[n] to calculate ted[n]. The TED algorithm can utilize two determined symbols of two digital samples corresponding to two consecutive phases (e.g., d[n−1] and d[n], or d[n] and d[n+1]) to calculate the timing error, ted[n].

Loop filter 310 may implement proportional and integral paths to perform robust phase tracking and frequency correction. For example, the proportional path responds to instantaneous phase error between the recovered clock information and incoming data transitions, providing fast correction to minimize jitter and phase deviation. In parallel, the integral path accumulates the phase error over time, enabling long-term frequency alignment and drift compensation. Link monitor 270 further includes PLL 312 to output a clock signal, clk[n], to one or more ADC slices 302 to close the clock recovery loop. PLL 312 can generate the clock signal based on the frequency control word, freq[n]. In some embodiments, PLL 312 is controlled through a divider ratio corresponding to N. As a result, the clock recovery circuit facilitates one or more ADC slices 302 to sample input 300 and lock onto the modulated signal in input 300. The clock recovery circuit can operate and lock to a proper sampling phase regardless of the type of data being observed by one or more ADC slices 302.

Equipped with one or more ADC slices 302 and a clock recovery circuit to sample the analog signal (e.g., input 300), link monitor 270 can include a link metrics extraction circuit to output one or more metrics of the communication link based on the one or more digital samples of the analog signal produced by one or more ADC slices 302.

In some embodiments, the link metrics extraction circuit comprises signal monitor circuit 314. Signal monitor circuit 314 can receive the one or more digital samples of the analog signal, e.g., one or more of x[n−1], x[n], and x[n+1], and generate a signal histogram based on the one or more digital samples of the analog signal, e.g., one or more of x[n−1], x[n], and x[n+1]. To generate a signal histogram, one or more ADC slices 302 in link monitor 270 samples input 300 at appropriate time intervals and converts input 300 into a series of one or more digital samples. The one or more digital samples are binned according to their amplitude levels, constructing a signal histogram that represents the statistical distribution of the signal over time. By accumulating the occurrence of each amplitude bin, the signal histogram provides insight into signal integrity, noise, and distortion characteristics within the communication link. Exemplary metrics that can be extracted from the signal histogram can include signal power, level separation, and symmetry. For example, it is possible to infer the noise power σ² in x[n].

When the communication link is transmitting a known or predetermined sequence, such as PRBS pattern, it is possible to use take the one or more determined symbols and reconstruct the PRBS pattern, since the function for producing the known or predetermined sequence is known. The reconstructed PRBS pattern can be used to calculate the impulse response h[n] of the link, by cross-correlating the digital samples of the signal and the reconstructed samples of the signal (or expected digital samples of the signal or what is being transmitted on the communication link). The impulse response h[n] characterizes the transfer function of the communication link (which can be represented as H[z] in the z-domain), where the sampled data is a result of a convolution of the impulse response h[n] with the transmitted data. The impulse response h[n] can be computed through correlation: h[n]=E{x[q]*d[q−n]}. The correlation equation can be rewritten to fix d and shift x in time instead: h[n]=E{x[q]*d[q−n]}=E{x[q+n]*d[q]}. In the equation, q can be any value and is not limited by the availability of three digital samples from one or more ADC slices 302 for a given n, e.g., x[n−1], x[n], and x[n+1]. Because the transmitted sequence is known and can be reconstructed, it is possible to compute d[q+n] or d[q−n] without the digital samples x[q+n] or x[q−n]. Cross-correlation of the one or more digital samples generated by one or more ADC slices 302 with the transmitted/reconstructed sequence allows the extraction of the link's impulse response h[n]. The impulse response allows for characterization of channel behavior, including ISI and other linear distortion effects.

In some embodiments, the link metrics extraction circuit comprises impulse response 318. Impulse response 318 can generate an impulse response h[n] of the link. The impulse response can be generated based on the one or more digital samples of the analog signal, e.g., one or more of x[n−1], x[n], and x[n+1], and one or more expected digital samples of the analog signal, e.g., d^{R}[n+p]. Impulse response 318 can include a digital circuit to calculate the expectation in the equation h[n]=E{x[q]*d[q−n]}=E{x[q+n]*d[q]}. The expectation can be computed based on an average of products of the two signals x and d over different time lags. The digital circuit can include shift registers to store past values of the digital samples and allow access to delayed versions of the signals for correlation. The digital circuit can include multipliers to multiply the signals to form the cross-correlation. The digital circuit can include accumulators (e.g., as running sums or averaging) to sum the products overtime to compute the expectation. Link monitor 270 includes pseudorandom sequence generator 320 to generate the one or more expected digital samples of the analog signal to be used in the cross-correlation. Pseudorandom sequence generator 320 can use a known function to reconstruct the transmitted sequence, e.g., a PRBS pattern, based on one or more of the determined symbols, e.g., d[n−1], d[n], and d[n+1], and output the one or more expected digital samples of the analog signal d^{R}[n+p].

Having signal monitor circuit 314 and impulse response 318 can offer a comprehensive view of the communication link. For example, the noise power σ² from the signal histogram produced by signal monitor circuit 314 can be used to compute the ISI power of the impulse response h[n]. The availability of the signal histogram (e.g., the noise power σ²) and the impulse response h[n] can allow for power analysis using the one or more digital samples available at the output of one or more ADC slices 302. For example, the one or more metrics that can be produced from the signal histogram and/or the impulse response h[n] can be used to optimize an equalizer in an unretimed interface (input 300 may be at an observation point upstream of the equalizer or an observation point downstream of the equalizer) and estimate the performance of the equalizer. In another example, the one or more metrics that can be produced from the signal histogram and/or the impulse response h[n] can be used to extract information to optimize the TX finite impulse response (FIR) on the TX ASIC or RX ASIC.

The implementation of link monitor 270 can be extended to accommodate a communication link that uses PAM4. PAM4 is a signal modulation technique that encodes data using four distinct voltage levels, allowing it to transmit 2 bits per symbol. PAM4 contrasts with NRZ modulation, which uses only two levels (0 and 1) and transmits 1 bit per symbol.

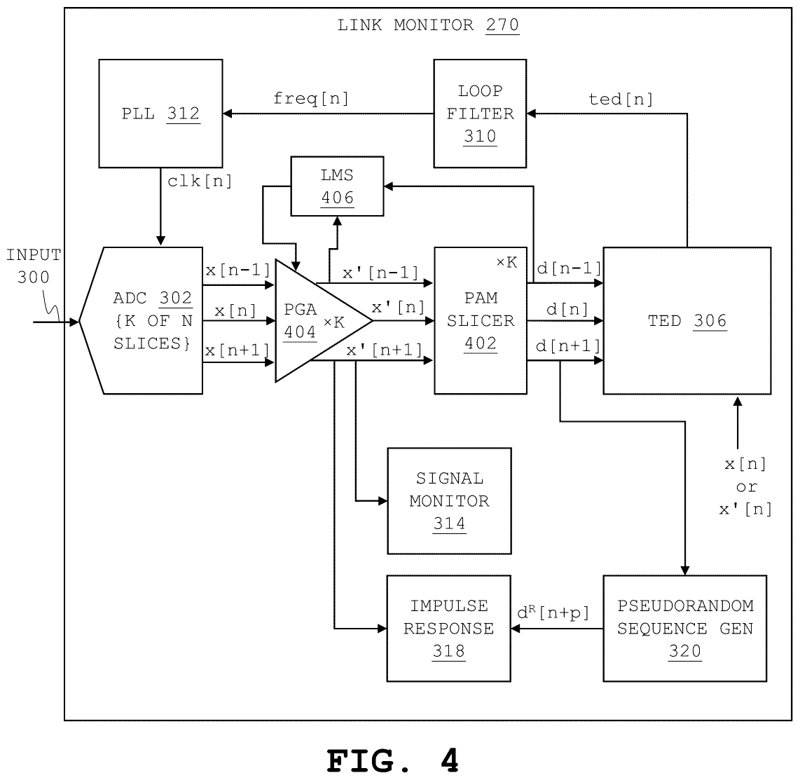

FIG. 4 illustrates an implementation of link monitor 270 in an unretimed interface processing a signal having a predetermined pseudorandom sequence with more than two signal levels, according to some embodiments of the disclosure. To accommodate sensing a signal with more than two signal levels (e.g., 3 levels, 4 levels, etc.), one or more PGAs 404 is added, and one or more slicers 304 may be modified to include one or more Pulse Amplitude Modulation (PAM) slicers 402. One or more PGAs 404 receives the one or more digital samples, e.g., x[n−1], x[n], and x[n+1], and amplifies the one or more digital samples to generate and output one or more (gain) adjusted digital samples, e.g., x′[n−1], x′[n], and x′[n+1]. One or more PAM slicers 402 can receive the one or more adjusted digital samples, e.g., x′[n−1], x′[n], and x′[n+1], and generate the one or more determined symbols, e.g., d[n−1], d[n], and d[n+1], using a plurality of thresholds to extract the symbol. The thresholds can be used to distinguish different symbols corresponding to more than two signal levels. The gain being applied by one or more PGAs 404 is adjustable by LMS 406 and can be used to restore or reconstruct the signal amplitude. LMS 406 can adapt the gain to improve the ability of one or more PAM slicers 402 to properly extract the determined symbol. To determine an appropriate gain, LMS 406 can receive an adjusted digital sample of the one or more adjusted digital samples (e.g., one or more of x′[n−1], x′[n], and x′[n+1]) and a determined symbol of the one or more determined symbols (e.g., one or more of d[n−1], d[n], and d[n+1]). Based on the adjusted digital sample and the determined symbol, LMS 406 can produce a gain control signal to control one or more PGAs 404 that optimizes the performance of one or more PAM slicers 402. LMS 406 can be used to adapt the gain and behavior of one or more PAM slicers 402 to varying link and channel conditions. In some implementations, LMS 406 can adjust the gain of one or more PGAs 404 by iteratively minimizing the mean squared error between a desired signal and the actual output. LMS 406 can update the gain control word in the direction opposite to the gradient of the error, effectively adapting to signal variations and link conditions in real time (e.g., including fluctuating signal amplitudes caused by link conditions or interference).

In some alternative implementation, the functionality of one or more PGAs 404 can be achieved by adaptively modifying the thresholds used in one or more PAM slicers 402, e.g., using LMS 406.

Pseudorandom sequence generator 320 can generate the one or more expected digital samples of the analog signal, e.g., d^{R}[n+p], to have more than two levels. Impulse response 318 may receive the one or more digital samples, e.g., one or more of x[n−1], x[n], and x[n+1]) and the one or more expected digital samples, e.g., d^{R}[n+p] to perform cross-correlation. Impulse response 318 may receive the one or more adjusted digital samples, e.g., one or more of x′[n−1], x′[n], and x′[n+1]) and the one or more expected digital samples, e.g., d^{R}[n+p] to perform cross-correlation.

In some scenarios, the unretimed interface may not be processing a predetermined sequence, e.g., a PRBS signal. The unretimed interface may be processing an unknown signal or traffic data being propagated on the communication link. It is still possible to compute the impulse response by including an ADC slice with a programmable sampling phase in link monitor 270. Suppose a full time-interleaved ADC has N slices (N=64, N=128), each sampling at a corresponding unit interval, the ADC slice with programmable phase can sample at any one of the UIs from 1 to N, and produce digital samples x[n+p] corresponding to a plurality of phases, time instances, or UIs, where p can vary from 0 to N−1. The digital samples spanning over the plurality of phases can be used as samples in the correlation for the impulse response, specifically for calculating the products of samples at different time lags (e.g., allowing d to be fixed in time and moving x in time). The one or more expected digital samples used in the correlation for the impulse response can be directly obtained from the one or more determined symbols at the output of the one or more slicers. The impulse response h[n] is thus calculated through h[n]=E{x[q+n] *d[q]} where x is shifted in time while d is fixed.

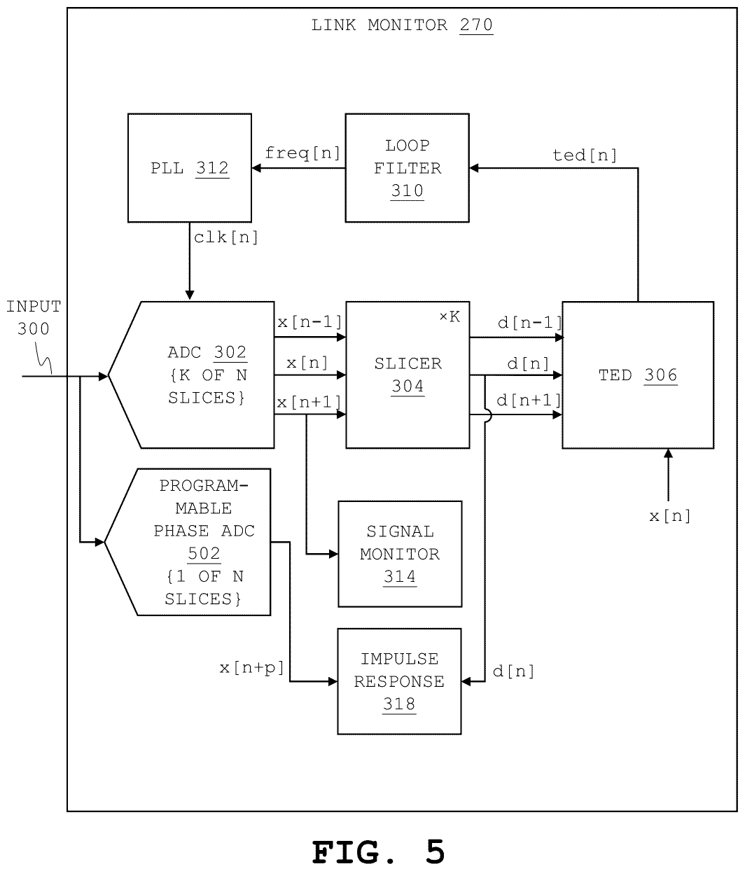

FIG. 5 illustrates an implementation of link monitor 270 in an unretimed interface employing mission mode, according to some embodiments of the disclosure. Link monitor 270 includes programmable phase ADC slice 502 with the programmable phase to produce the one or more digital samples corresponding to a plurality of phases, e.g., x[n+p] where p can vary from 0 to N−1. The one or more digital samples corresponding to the plurality of phases, e.g., x[n+p], and the one or more determined symbols, e.g., one or more of d[n−1], d[n], and d[n+1], can be passed as input to impulse response 318. Utilizing the programmable phase ADC slice 502 in link monitor 270 is referred to as operating link monitor 270 in mission mode.

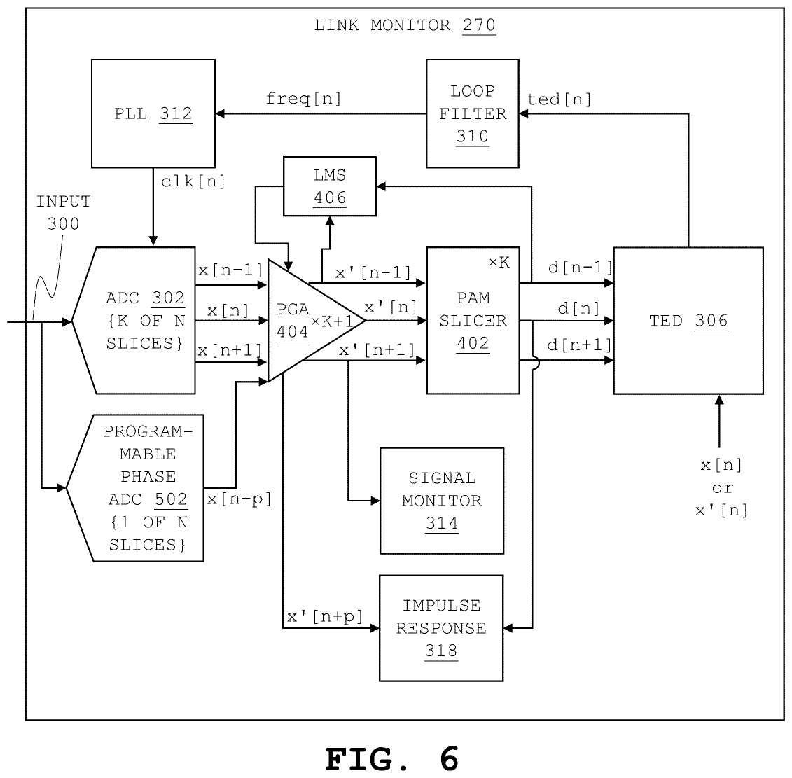

FIG. 6 illustrates an implementation of link monitor 270 in an unretimed interface processing a signal having a predetermined pseudorandom sequence with more than two signal levels and employing mission mode, according to some embodiments of the disclosure. Mission mode can be applied to link monitor 270 as illustrated in FIG. 4. The one or more digital samples corresponding to the plurality of phase, e.g., x[n+p] can be provided as input to one or more PGAs 404 to generate one or more adjusted digital samples, e.g., x′[n+p], In some embodiments, one PGA can be added to one or more PGAs 404 to amplify the output of programmable phase ADC slice 502. The one or more adjusted digital samples, e.g., x′[n+p], and the one or more determined symbols, e.g., one or more of d[n−1], d[n], and d[n+1], can be passed as input to impulse response 318.

Utilizing link monitor 270 as illustrated in FIGS. 3-6 can extract an impulse response based on one or more digital samples that are sampled at BR of the communication link. In some scenarios, obtaining an oversampled impulse response can offer information about the communication link. For example, finer impairments on the channel, including ISI where overlapping signals degrade performance, rare events, and higher-order non-linearities can be extracted from the oversampled impulse response. BR is usually quite fast already, and implementing an oversampling ADC is not practical. To offer an efficient link monitor, it is possible to modify the clock recovery circuit in the link monitor to lock to a slight frequency offset of BR, e.g., a rational fraction of the BR, and use the fractional clock to drive an ADC slice to sample at the rational fraction of the BR over many repeating periods of the pseudorandom sequence. The one or more digital samples produced at the rational fraction of the BR over many sampling periods can be used to reconstruct an oversampled impulse response. Operating the link monitor in this manner is referred to as sampling scope mode.

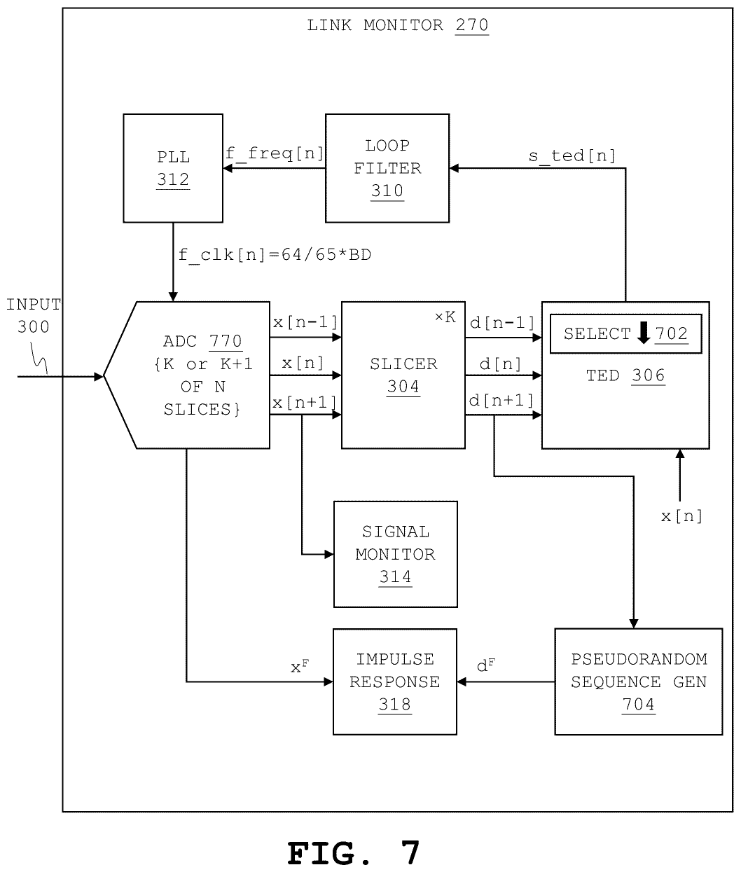

FIG. 7 illustrates an implementation of link monitor 270 to extract an oversampled impulse response, according to some embodiments of the disclosure. In an illustrative example, the clock recovery circuit of link monitor 270 can lock to (P−1)/P=(64/65)*BR, by downsampling the timing error, ted[n] at a downsampling rate of P or 1 out of P, where P=65. TED 306 includes selection circuit 702 to perform selection or downsampling of timing errors and output a selected or downsampled timing error, s_ted[n]. The feedback loop action of the clock recovery circuit having loop filter 310 that is driving the timing error, s_ted[n], to be zero, can cause the clock recovery circuit to lock at a unique stable operating point that is not the BR. Specifically, the downsampling rate of P can cause the loop filter 310 to output a frequency control word, f_freq[n], that would control PLL 312 to produce a fractional clock signal, f_clk[n], at a rational fraction of BR, such as (P+1)/P*BR or (P−1)/P*BR. If P is sufficiently large, the clock signal can have a frequency near BR but not at BR. In the illustration, the fractional clock signal f_clk[n] has a clock frequency that is a rational fraction of BR, e.g., 64/65*BD. The clock signal near BR, f_clk[n] can be used by one or more time-interleaved ADC slices to achieve oversampling of a predetermined periodic signal or sequence at input 300, by performing sampling of the periodic signal or sequence over one or more or many periods or cycles of the periodic signal or sequence. The closer to BR, the finer, higher resolution samples or higher effective oversampling rate can be achieved.

Besides implementing fractional lock, link monitor 270 includes one or more ADC slices 770 that is able to collect samples that correspond to different fractional phases within a unit interval, e.g., samples on a grid of 1/64 unit interval if the lock frequency is set to 64/65*BD. Normally, N ADC slices take turn sampling the input one after another over N=64 phases to produce digital samples across the N=64 phases. In some embodiments, the ADC slice in one or more ADC slices 770 can have a programmable sampling phase that spans all 64 phases (e.g., N=64), where p can be varied between 0 to 63, and the ADC slice can be driven by the fractional clock signal produced by PLL 312 to operate in a sampling scope mode. Because of the slight frequency offset of the fractional clock signal, f_clk[n] with a frequency near BR, the ADC slice driven by the fractional clock signal can produce digital samples at sub-UI positions, x^{F}, as p varies between 0 and 63. Since PRBS length is a prime number, n and p can be varied to sample the entire PRBS pattern. The produced digital samples produced by the ADC slice are equivalent to having an oversampling ADC slice producing samples at sub-UI positions.

The digital samples having phases corresponding to fractional phases within a unit interval, x^{F}, can be provided as input to impulse response 318. Link monitor 270 further includes pseudorandom sequence generator 704 to generate the one or more expected digital samples, d^{F}, based on a predetermined periodic signal being sampled at the rational fraction of the BR. Impulse response 318 may receive the one or more digital samples sampled at fractional phases within a unit interval, e.g., x^{F}, and the one or more expected digital samples, e.g., d^{F}, to perform cross-correlation and extract the oversampled impulse response. Obtaining an oversampled impulse response can offer a finer view of the signal behavior within a UI and can allow for more effective characterization of distortions such as ISI, timing jitter, and other eye diagram characteristics with higher precision.

In some alternative implementations, the number of ADC slices being used to sample the analog signal can be further reduced down to just a single ADC slice. This reduction in complexity can be realized because the previous and subsequent determined symbols, e.g., d[n−1] and d[n+1], being used by TED 306 to calculate the timing error, can be generated by the pseudorandom sequence generator using the current determined symbol, e.g., d[n], since the pseudorandom sequence is known.

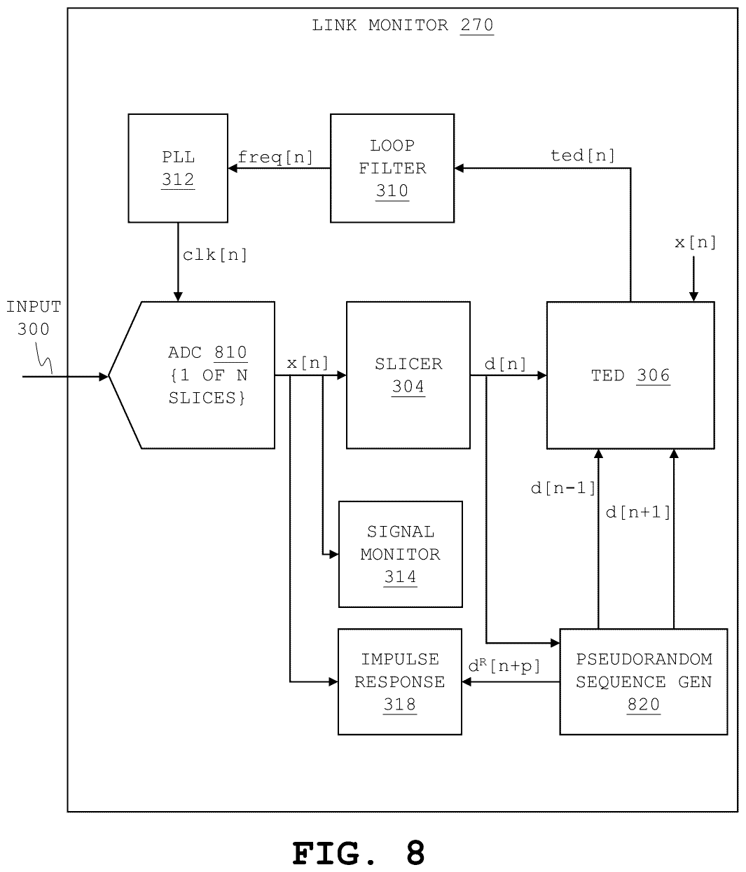

FIG. 8 illustrates an implementation of link monitor 270 employing a single ADC slice, according to some embodiments of the disclosure. Link monitor 270 as illustrated in FIG. 8 can be a trimmed down version of link monitor 270 as illustrated in FIG. 3. As shown, link monitor 270 includes a single ADC slice 810. Single ADC slice 810 generates a digital sample, x[n], and (a single) slicer 304 can generate a determined symbol, d[n], based on the digital sample. The digital sample, x[n], can be provided as input to signal monitor circuit 314 to extract a signal histogram. The digital sample, x[n], can be provided as input to impulse response 318 to extract an impulse response. Using a single ADC slice 810 means that pseudorandom sequence generator 820 will supplement by generating one or more further determined symbols, e.g., one or more of d[n−1] and d[n+1]. Pseudorandom sequence generator 820 can receive a determined symbol, e.g., d[n], and based on the determined symbol, generate and output the one or more further determined symbols, e.g., one or more of d[n−1] and d[n+1]. The clock recovery circuit, e.g., TED 306, can receive the determined symbol, e.g., d[n], from (a single) slicer 304, and the one or more further determined symbols, e.g., one or more of d[n−1] and d[n+1].

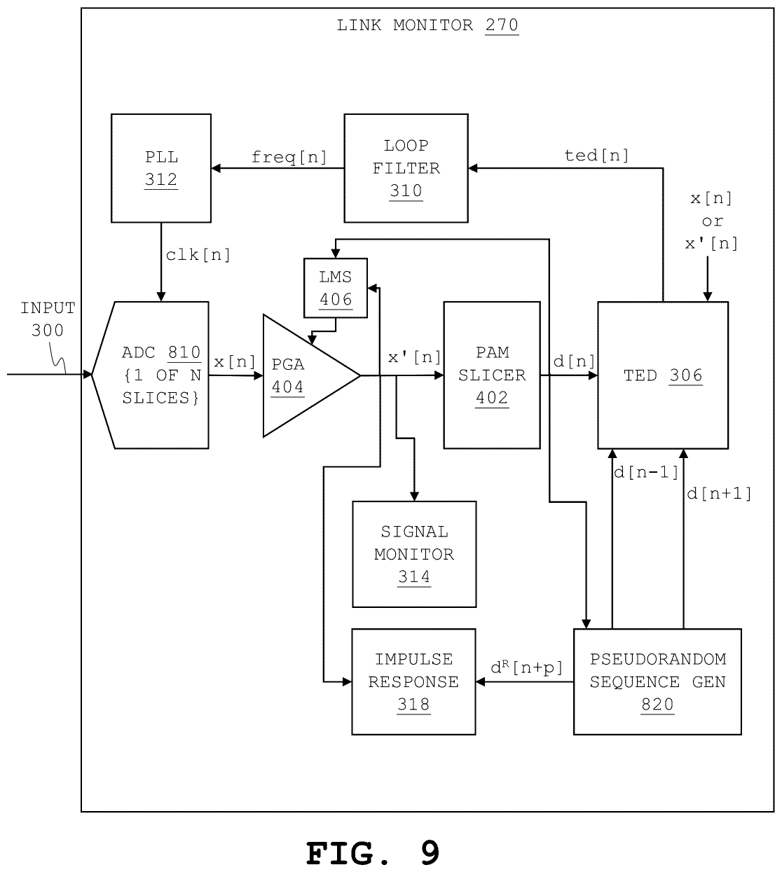

FIG. 9 illustrates an implementation of link monitor 270 employing a single ADC slice and processing a signal having a predetermined pseudorandom sequence with more than two signal levels, according to some embodiments of the disclosure. Link monitor 270 as illustrated in FIG. 9 can be a trimmed down version of link monitor 270 as illustrated in FIG. 4. As shown, link monitor 270 includes a single ADC slice 810. Single ADC slice 810 generates a digital sample, x[n]. The digital sample can be amplified by (a single) PGA 404 to obtain an adjusted digital sample, x′[n]. The adjusted digital sample, x′[n], is provided as input into (a single) PAM slicer 402, which can generate a determined symbol, d[n], based on the adjusted digital sample, x′[n]. The adjusted digital sample, x′[n], can be provided as input to signal monitor circuit 314 to extract a signal histogram. The adjusted digital sample, x′[n], can be provided as input to impulse response 318 to extract an impulse response. Using a single ADC slice 810 means that pseudorandom sequence generator 820 will supplement by generating one or more further determined symbols, e.g., one or more of d[n−1] and d[n+1]. Pseudorandom sequence generator 820 can receive a determined symbol, e.g., d[n], and based on the determined symbol, generate and output the one or more further determined symbols, e.g., one or more of d[n−1] and d[n+1]. The clock recovery circuit, e.g., TED 306, can receive the determined symbol, e.g., d[n], from (a single) PAM slicer 402, and the one or more further determined symbols, e.g., one or more of d[n−1] and d[n+1].

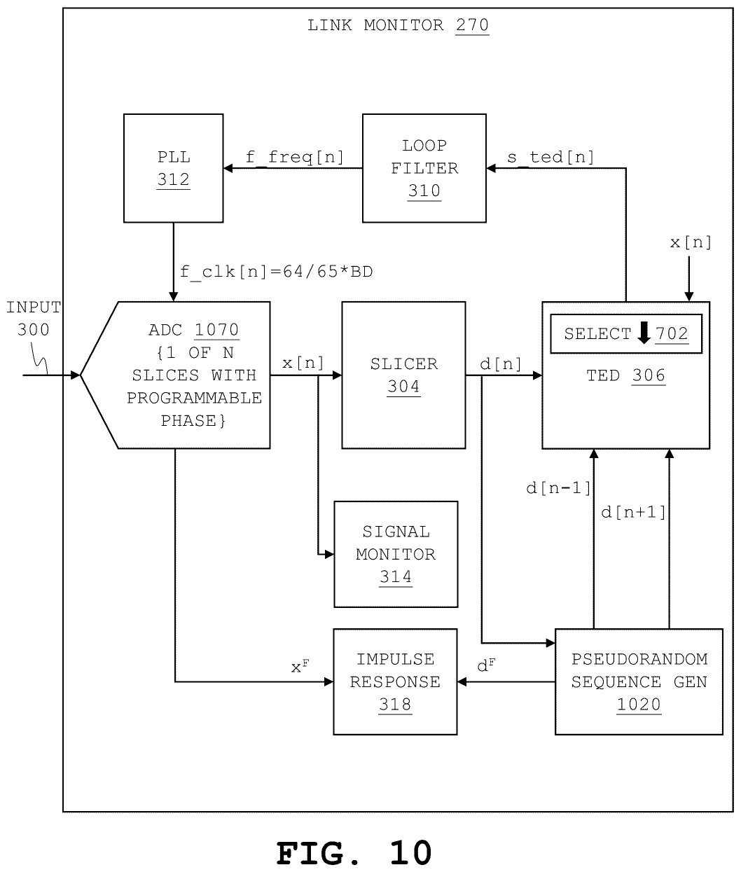

FIG. 10 illustrates an implementation of link monitor 270 employing a single ADC slice and extracting an oversampled impulse response, according to some embodiments of the disclosure. Link monitor 270 as illustrated in FIG. 10 can be a trimmed down version of link monitor 270 as illustrated in FIG. 7. As shown, link monitor 270 includes a single ADC slice 1070. Single ADC slice 1070 generates a digital sample, x[n]. The digital sample, x[n], can be provided as input to (a single) slicer 304, which can generate a determined symbol, d[n], based on the digital sample, x[n]. The digital sample, x[n], can be provided as input to signal monitor circuit 314 to extract a signal histogram. Using a single ADC slice 810 means that pseudorandom sequence generator 820 will supplement by generating one or more further determined symbols, e.g., one or more of d[n−1] and d[n+1]. Pseudorandom sequence generator 1020 can receive a determined symbol, e.g., d[n], and based on the determined symbol, generate and output the one or more further determined symbols, e.g., one or more of d[n−1] and d[n+1]. The clock recovery circuit, e.g., TED 306, can receive the determined symbol, e.g., d[n], from (a single) slicer 304, and the one or more further determined symbols, e.g., one or more of d[n−1] and d[n+1].

In some embodiments, the clock recovery circuit of link monitor 270 can achieve fractional clock to drive single ADC slice 1070 at near BR, such as a rational fraction of BR, and single ADC slice 1070 can have a programmable phase. Single ADC slice 1070 can produce digital samples corresponding to sub-UI positions, e.g., x^{F}. Pseudorandom sequence generator 1020 can generate the one or more expected digital samples based on a predetermined periodic signal being sampled at the rational fraction of the BR. The digital samples corresponding to sub-UI positions, e.g., x^{F}, and the one or more expected digital samples, e.g., d^{F} can be provided to impulse response 318 to perform cross-correlation and extract an oversampled impulse response.

The locking capabilities of the clock recovery circuit of link monitor 270 can be improved through DFE. DFE is a nonlinear equalizer that can be used to mitigate ISI. DFE can subtract the estimated ISI caused by one or more previous determined symbols from the current digital sample. A one-tap DFE equation can be represented as: d[n]=slicer (x[n]−dfe*d[n−1]), where dfe represents a filter coefficient, x[n] is a current digital sample generated by an ADC slice, and d[n−1] can be generated by the pseudorandom sequence generator, and slicer ( ) is the function performed by the slicer, e.g., a PAM slicer. A one-tap DFE can utilize one previous determined symbol and one DFE coefficient. Multi-tap DFE can utilize two or more previous determined symbols and two or more DFE coefficients. DFE can be implemented in link monitor 270 efficiently when link monitor 270 is operating on known PRBS data. A feedback loop can be bypassed or avoided when the previous determined symbol, e.g., d[n−1], can be generated deterministically. As a result, DFE can be implemented simply because high-speed feedback paths are obviated. DFE can be useful for the locking capabilities of the clock recovery circuit because the inputs used by the clock recovery circuits are cleaner and less impacted by ISI, and the clock recovery circuit can lock to the signal more reliably. DFE can be particularly useful when more than two signal levels are used to modulate the signal, e.g., PAM4, since these modulation schemes are more susceptible to ISI.

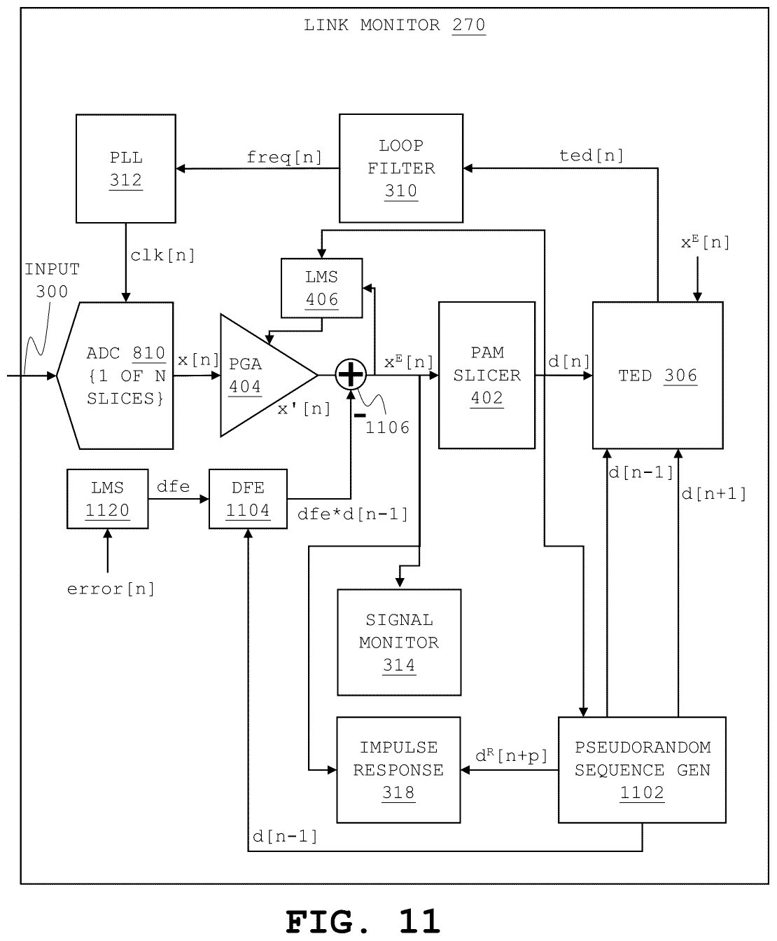

FIG. 11 illustrates an implementation of link monitor 270 employing a single ADC slice and applying DFE, according to some embodiments of the disclosure. Link monitor 270 as illustrated in FIG. 11 can be modified version of link monitor 270 as illustrated in FIG. 9. Modifications include using pseudorandom sequence generator 1102 to generate one or more previous expected digital samples, e.g., d[n−1], addition of LMS 1120, addition of DFE 1104, addition of adder 1106, and having (a single) PAM slicer 402 receive an equalized adjusted digital sample, e.g., x^{E}[n] as input.

Using a single ADC slice 810 means that pseudorandom sequence generator 1102 will supplement by generating one or more further determined symbols, e.g., one or more of d[n−1] and d[n+1]. Pseudorandom sequence generator 1102 can receive a determined symbol, e.g., d[n], and based on the determined symbol, generate and output the one or more further determined symbols, e.g., one or more of d[n−1] and d[n+1]. The clock recovery circuit, e.g., TED 306, can receive the determined symbol, e.g., d[n], from (a single) PAM slicer 402, and the one or more further determined symbols, e.g., one or more of d[n−1] and d[n+1].

LMS 1120 can receive an error signal, error [n], and output one or more filter coefficients, e.g., dfe. In some embodiments, the error signal, error [n], is based on the known PRBS symbol (e.g., produced by pseudorandom sequence generator 1102) and the output of slicer 402, e.g., d[n]. The error signal, error [n], can measure the difference between the known PRBS symbol and the output of slicer 402, e.g., d[n]. LMS 1120 can update the one or more filter coefficients to reduce the error signal, e.g., error [n]. DFE 1104 can receive the one or more previous expected digital samples from pseudorandom sequence generator 1102, and the one or more filter coefficients, e.g., dfe, from LMS 1120. DFE 1104 can apply the one or more filter coefficients, e.g., dfe, to the one or more previous expected digital samples, e.g., d[n−1], to produce a correction signal, e.g., dfe*d[n−1]. Adder 1106 can be used to apply (e.g., add or subtract) the correction signal, e.g., dfe*d[n−1] to a signal upstream of PAM slicer 402, e.g., x′[n], to generate the equalized adjusted digital sample, e.g., x[n].

Impulse response 318 may receive the digital samples, e.g., x[n] and the one or more expected digital samples, e.g., d^{R}[n+p] to perform cross-correlation. Impulse response 318 may receive the one or more adjusted digital samples, e.g., x′[n] and the one or more expected digital samples, e.g., d^{R}[n+p] to perform cross-correlation. Impulse response 318 may receive the equalized adjusted digital sample, e.g., x^{E}[n], and the one or more expected digital samples, e.g., d^{R}[n+p] to perform cross-correlation.

### Extracting Conditional Statistics by the Link Monitor

In some scenarios, having one or more metrics that are conditioned on one or more conditions can offer additional information about the link status, such as link status information and performance under different operating conditions of the communication link. Conditional metrics or statistics (e.g., averages, variances, signal histograms, impulse responses, etc.) calculated when one or more conditions are met in the data can be particularly useful for understanding how the communication link is behaving under specific signal patterns, transitions, or signal levels.

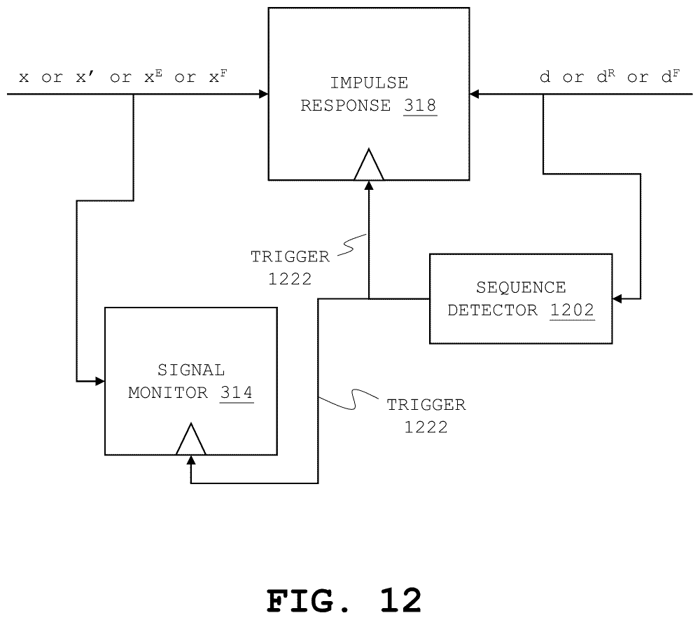

FIG. 12 illustrates extracting conditional statistics based on detecting a particular sequence, according to some embodiments of the disclosure. A link monitor further includes sequence detector 1202 to detect whether a specific signal pattern or subsequence has been received. Sequence detector 1202 can receive the one or more determined symbols (e.g., d, d^{R}, and/or d^{E}) and determine whether the one or more determined symbols match a specific signal pattern or subsequence. Sequence detector 1202 can output trigger signal 1222 based on detecting that the one or more determined symbols (e.g., d, d^{R}, and/or d^{E}) match a predetermined sequence of symbols. Trigger signal 1222 can trigger a link metrics extraction circuit, e.g., signal monitor circuit 314 and/or impulse response 318, to extract the one or more metrics of the communication link.

In one example, sequence detector 1202 checks for the occurrence of a specific bit or symbol pattern, e.g., 101 or +1, −1, +3, and outputs trigger signal 1222 upon detecting the occurrence. The metrics being extracted under this condition can reveal how the communication link is behaving to specific data transitions or ISI-inducing patterns. Various metrics extracted under different conditions (e.g., different signal patterns or subsequences) can be compared with each other. The communication link may behave differently after a long run of zeros versus a transition-heavy sequence.

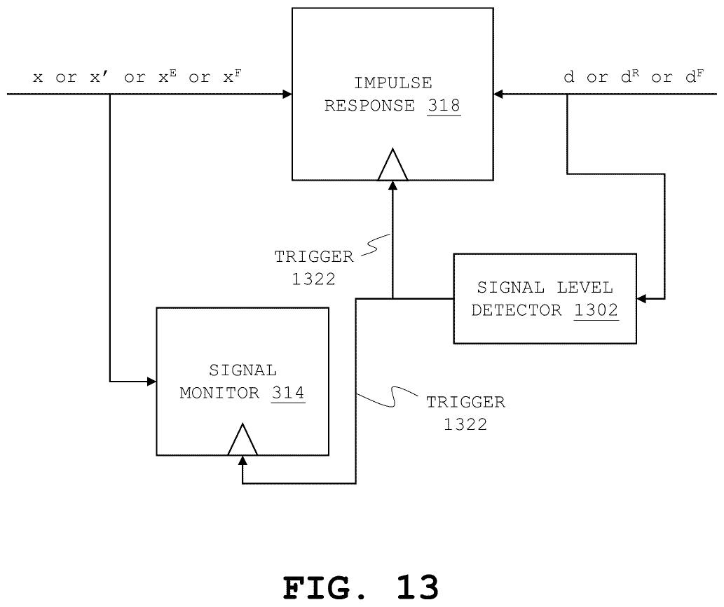

FIG. 13 illustrates extracting conditional statistics based on detecting a signal level condition, according to some embodiments of the disclosure. A link monitor further includes signal level detector 1302 to detect whether the one or more determined symbols meet a predetermined signal level condition (e.g., a particular signal level, or range of signal levels). Signal level detector 1302 can receive the one or more determined symbols (e.g., d, d^{R}, and/or d^{E}) and determine whether the one or more determined symbols match a signal level condition. Signal level detector 1302 can output trigger signal 1322 based on detecting that the one or more determined symbols (e.g., d, d^{R}, and/or d^{E}) match a signal level condition. Trigger signal 1322 can trigger a link metrics extraction circuit, e.g., signal monitor circuit 314 and/or impulse response 318, to extract the one or more metrics of the communication link.

In one example, signal level detector 1302 checks if the one or more determined symbols (e.g., d, d^{R}, and/or d^{E}) meet a specific signal level (e.g., −1 for NRZ, or +3 if PAM4 is used). The metrics being extracted under this signal condition can reveal how the communication link is behaving at different transmitted levels. Various metrics extracted under different conditions (e.g., different signal levels) can be compared with each other. Average or impulse response under different conditions can reveal level-dependent distortions like non-linearities or asymmetric ISI.

### Methods for Link Monitoring in an Unretimed Interface

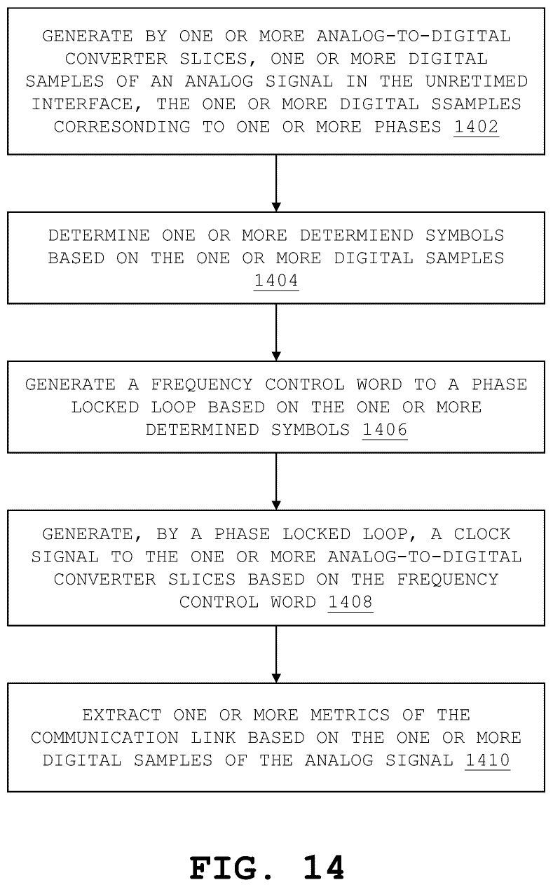

FIG. 14 depicts a flow chart illustrating method 1400 for link monitoring in an unretimed interface coupled to a communication link, according to some embodiments of the disclosure. Method can be performed by link monitor 270 as described and illustrated herein.

In 1402, one or more ADC slices generates one or more digital samples of an analog signal in the unretimed interface, the one or more digital samples corresponding to one or more phases.

In 1404, one or more slicers can determine one or more determined symbols based on the one or more digital samples.

In 1406, a clock recovery circuit can generate a frequency control word to a phase locked loop based on the one or more determined symbols.

In 1408, a PLL or NCO can generate a clock signal to the one or more ADC slices based on the frequency control word.

In 1410, a link metrics extraction circuit can extract one or more metrics of the communication link based on the one or more digital samples of the analog signal.

In some embodiments, extracting the one or more metrics can include generating a signal histogram based on the one or more digital samples of the analog signal (or a derivation thereof).

In some embodiments, extracting the one or more metrics comprises generating an impulse response of the link based on the one or more digital samples of the analog signal (or a derivation thereof) and one or more expected digital samples of the analog signal. In some embodiments, a pseudorandom sequence generator generates the one or more expected digital samples of the analog signal.

In some embodiments, a programmable phase ADC slice can digitize the analog signal across a number of UIs and generate the one or more digital samples. The programmable phase ADC thus operates in mission mode. The one or more expected digital samples of the analog signal used in generating the impulse response can be based on a determined symbol of the one or more determined symbols from the slicer (as opposed to from a pseudorandom sequence generator).

In some embodiments, extracting the one or more metrics comprises applying a programmable gain to the one or more digital samples of the analog signal to obtain one or more adjusted digital samples, and extracting the one or more metrics based on the one or more adjusted digital samples.

In some embodiments, generating the frequency control word comprises generating, by a pseudorandom sequence generator, one or more further determined symbols (e.g., previous and/or subsequent determined symbol) based on a determined symbol of the one or more determined symbols (e.g., current determined symbol), and generating the frequency control word further based on one or more further determined symbols.

In some embodiments, generating the frequency control word comprises downsampling one or more timing errors. Downsampling or selecting the timing errors at a suitable downsampling rate causes the clock signal to lock a clock frequency that is a rational fraction of a BR of the communication link. The digital samples produced by the one or more ADC slices have phases that correspond to fractional phases within a unit interval. The digital samples can be used to produce an oversampled impulse response. In some embodiments, extracting the one or more metrics comprises generating one or more expected digital samples based on a predetermined periodic signal being sampled at the rational fraction of the BR and generating an oversampled impulse response of the link based on the one or more digital samples of the analog signal at fractional phases within the UI and the one or more expected digital samples of the analog signal sampled at the rational fraction of the BR

In some embodiments, a pseudorandom sequence generator generates one or more previous expected digital samples. A decision feedback equalizer can apply one or more filter coefficients to the one or more previous expected digital samples to generate a correction signal. The correction signal to a signal of one or more slicers.

In some embodiments, extracting the one or more metrics comprises triggering the extracting of the one or more metrics based on detecting that the one or more determined symbols match a predetermined sequence of symbols.

In some embodiments, extracting the one or more metrics comprises triggering the extracting of the one or more metrics based on detecting that the one or more determined symbols meet a predetermined signal level condition.

### SELECT EXAMPLES

Example 1 provides an integrated circuit for link monitoring a performance across an unretimed interface, including one or more analog-to-digital converter slices to receive an analog signal in the unretimed interface and output one or more digital samples of the analog signal corresponding to one or more phases, the unretimed interface coupled to a communication medium of a communication link; one or more slicers to output one or more determined symbols based on the one or more digital samples; a clock recovery circuit to receive the one or more determined symbols and output a frequency control word to a phase locked loop; the phase locked loop to output a clock signal to the one or more analog-to-digital converter slices based on the frequency control word; and a link metrics extraction circuit to output one or more metrics of the communication link based on the one or more digital samples of the analog signal.

Example 2 provides the integrated circuit of example 1, where the link metrics extraction circuit includes a signal monitor circuit to generate a signal histogram based on the one or more digital samples of the analog signal.

Example 3 provides the integrated circuit of example 1 or 2, where the link metrics extraction circuit includes an impulse response circuit to generate an impulse response of the communication link based on the one or more digital samples of the analog signal and one or more expected digital samples of the analog signal.

Example 4 provides the integrated circuit of example 3, further including a pseudorandom sequence generator to generate the one or more expected digital samples of the analog signal.

Example 5 provides the integrated circuit of example 3, where: the one or more analog-to-digital converter slices include an analog-to-digital converter slice having a programmable phase; the one or more phases correspond to a plurality of phases; and the one or more expected digital samples of the analog signal are based on the one or more determined symbols output by a slicer of the one or more slicers.

Example 6 provides the integrated circuit of any one of examples 1-5, further including a programmable gain stage to receive the one or more digital samples of the analog signal and output one or more adjusted digital samples; a least means square circuit to receive an adjusted digital sample of the one or more adjusted digital samples and a determined symbol of the one or more determined symbols and to control the programmable gain stage; a slicer of the one or more slicers generates the determined symbol of the one or more determined symbols using a plurality of thresholds; and the one or more slicers to receive the one or more adjusted digital samples.

Example 7 provides the integrated circuit of any one of examples 1-6, where: the one or more analog-to-digital converter slices include three analog-to-digital converter slices; and the one or more phases correspond to three consecutive phases.

Example 8 provides the integrated circuit of any one of examples 1-6, where: the one or more analog-to-digital converter slices include two analog-to-digital converter slices; and the one or more phases correspond to two consecutive phases.

Example 9 provides the integrated circuit of any one of examples 1-6, where: the one or more analog-to-digital converter slices include a single analog-to-digital converter slice; the integrated circuit further includes a pseudorandom sequence generator to receive a determined symbol of the one or more determined symbols and output one or more further determined symbols; and the clock recovery circuit receives the one or more further determined symbols.

Example 10 provides the integrated circuit of any one of examples 1-9, where: the clock recovery circuit includes a circuit configured to select and output a selected timing error from one or more timing errors; the clock signal output by the phase locked loop has a clock frequency that is a rational fraction of a Baud Rate of the communication link; and the one or more phases correspond to fractional phases within a unit interval.

Example 11 provides the integrated circuit of example 10, where: the link metrics extraction circuit includes an oversampled impulse response circuit to generate an oversampled impulse response of the communication link based on the one or more digital samples of the analog signal and one or more expected digital samples of the analog signal; and the integrated circuit further includes a pseudorandom sequence generator to generate the one or more expected digital samples based on a predetermined periodic signal being sampled at the rational fraction of the Baud Rate.

Example 12 provides the integrated circuit of any one of examples 1-11, further including a pseudorandom sequence generator to generate a previous expected digital sample; a least means square circuit to receive an error signal and output one or more filter coefficients; a decision feedback equalizer to receive the previous expected digital sample and the one or more filter coefficients and output a correction signal; and an adder to apply the correction signal to a signal upstream of the one or more slicers.

Example 13 provides the integrated circuit of any one of examples 1-12, further including a sequence detector to receive the one or more determined symbols and output a trigger signal based on detecting that the one or more determined symbols match a predetermined sequence of symbols, where the trigger signal triggers the link metrics extraction circuit to extract the one or more metrics of the communication link.

Example 14 provides the integrated circuit of any one of examples 1-13, further including a signal level detector to receive the one or more determined symbols and output a trigger signal based on detecting that the one or more determined symbols meet a predetermined signal level condition, where the trigger signal triggers the link metrics extraction circuit to extract the one or more metrics of the communication link. <b></b>

Example 15 provides an unretimed optical interface with link monitoring, including optics circuitry coupled to a communication medium of a communication link; one or more analog circuits coupled to the optics circuitry; and a link monitor including one or more analog-to-digital converter slices to receive an analog signal of the one or more analog circuits and output one or more digital samples of the analog signal corresponding to one or more phases; one or more slicers to output one or more determined symbols based on the one or more digital samples; a clock recovery circuit to receive the one or more determined symbols and output a frequency control word to a phase locked loop; the phase locked loop to output a clock signal to the one or more analog-to-digital converter slices based on the frequency control word; and a link metrics extraction circuit to output one or more metrics of the communication link based on the one or more digital samples of the analog signal.

Example 16 provides the unretimed optical interface of example 15, where: the one or more analog circuits include a programmable gain amplifier; and the analog signal of the one or more analog circuits is an input to the programmable gain amplifier or an output of the programmable gain amplifier.

Example 17 provides the unretimed optical interface of example 15, where: the one or more analog circuits include an equalizer; and the analog signal of the one or more analog circuits is an input to the equalizer or an output of the equalizer.

Example 18 provides the unretimed optical interface of example 15, where: the one or more analog circuits include a transimpedance amplifier; and the analog signal of the one or more analog circuits is an input to the transimpedance amplifier or an output of the transimpedance amplifier.

Example 19 provides the unretimed optical interface of example 15, where: the one or more analog circuits include a transconductance amplifier; and the analog signal of the one or more analog circuits is an input to the transconductance amplifier or an output of the transconductance amplifier.

Example 20 provides the unretimed optical interface of any one of examples 15-19, where the link monitor further includes one or more aspects recited in any one of examples 2-14.

Example 21 provides a method for link monitoring in an unretimed interface coupled to a communication medium of a communication link, including generating, by one or more analog-to-digital converter slices, one or more digital samples of an analog signal in the unretimed interface, the one or more digital samples corresponding to one or more phases; determining one or more determined symbols based on the one or more digital samples; generating a frequency control word to a phase locked loop based on the one or more determined symbols; generating, by a phase locked loop, a clock signal to the one or more analog-to-digital converter slices based on the frequency control word; and extracting one or more metrics of the communication link based on the one or more digital samples of the analog signal.

Example 22 provides the method of example 21, where extracting the one or more metrics includes generating a signal histogram based on the one or more digital samples of the analog signal.

Example 23 provides the method of example 21 or 22, where extracting the one or more metrics includes generating an impulse response of the communication link based on the one or more digital samples of the analog signal and one or more expected digital samples of the analog signal.

Example 24 provides the method of example 23, further including generating the one or more expected digital samples of the analog signal by a pseudorandom sequence generator.

Example 25 provides the method of example 23, where: generating the one or more digital samples includes digitizing the analog signal across a number of unit intervals; the one or more expected digital samples of the analog signal are based on a determined symbol of the one or more determined symbols.

Example 26 provides the method of any one of examples 21-25, where extracting the one or more metrics includes applying a programmable gain to the one or more digital samples of the analog signal to obtain one or more adjusted digital samples; and extracting the one or more metrics based on the one or more adjusted digital samples.

Example 27 provides the method of any one of examples 21-26, where generating the frequency control word includes generating, by a pseudorandom sequence generator, one or more further determined symbols based on a determined symbol of the one or more determined symbols; and generating the frequency control word further based on one or more further determined symbols.

Example 28 provides the method of any one of examples 21-27, where: generating the frequency control word includes downsampling one or more timing errors; the clock signal is locked a clock frequency that is a rational fraction of a Baud Rate of the communication link; and the one or more phases correspond to fractional phases within a unit interval.

Example 29 provides the method of example 28, where extracting the one or more metrics includes generating one or more expected digital samples based on a predetermined periodic signal being sampled at the rational fraction of the Baud Rate; and generating an oversampled impulse response of the link based on the one or more digital samples of the analog signal and the one or more expected digital samples of the analog signal.

Example 30 provides the method of any one of examples 21-29, further including generating, by a pseudorandom sequence generator a previous expected digital sample; applying, by a decision feedback equalizer, one or more filter coefficients to the previous expected digital sample to generate a correction signal; and applying the correction signal to a signal upstream of one or more slicers.

Example 31 provides the method of any one of examples 21-30, where extracting the one or more metrics includes triggering the extracting of the one or more metrics based on detecting that the one or more determined symbols match a predetermined sequence of symbols.

Example 32 provides the method of any one of examples 21-31, where extracting the one or more metrics includes triggering the extracting of the one or more metrics based on detecting that the one or more determined symbols meet a predetermined signal level condition.

Example 33 provides an apparatus having means for performing the method of any one of examples 21-32.

Example 34 provides a linear pluggable optics interface having one or more aspects recited in any one of examples 1-20.

### Variations and Other Notes

The detailed description, such as the “Select examples” section, provide various examples of the embodiments disclosed herein.

As used herein, the term “coupled to” or “coupled with” refers to a relationship between electronic components or circuit elements wherein the components are in electronic communication with one another and capable of transmitting and/or receiving electrical signals between them. The term “coupled to” does not require a direct physical or electrical connection between the coupled components. Rather, “coupled to” can encompass arrangements where the components are connected through one or more intervening elements, components, circuits, or transmission paths. For example, a first component may be “coupled to” a second component through intermediate components such as resistors, capacitors, inductors, transistors, logic gates, buses, transformers, or other electronic components, or through intermediate transmission paths, while still maintaining the capability for electronic communication between the first and second components.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

For purposes of explanation, specific numbers, materials and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well known features are omitted or simplified in order not to obscure the illustrative implementations.

Further, references are made to the accompanying drawings that form a part hereof, and in which are shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the disclosed subject matter. However, the order of description should not be construed as to imply that these operations are necessarily order dependent. In particular, these operations may not be performed in the order of presentation. Operations described may be performed in a different order from the described embodiment. Various additional operations may be performed or described operations may be omitted in additional embodiments.

For the purposes of the present disclosure, the phrase “A or B” or the phrase “A and/or B” means (A), (B), or (A and B). For the purposes of the present disclosure, the phrase “A, B, or C” or the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side” to explain various features of the drawings, but these terms are simply for ease of discussion, and do not imply a desired or required orientation. The accompanying drawings are not necessarily drawn to scale. Unless otherwise specified, the use of the ordinal adjectives “first,” “second,” and “third,” etc., to describe a common object, merely indicates that different instances of like objects are being referred to and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art.

The terms “substantially,” “close,” “approximately,” “near,” and “about,” generally refer to being within +/−20% of a target value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value as described herein or as known in the art.

In addition, the terms “comprise,” “comprising,” “include,” “including,” “have,” “having” or any other variation thereof, are intended to cover a non-exclusive inclusion. For example, a method, process, or device, that comprises a list of elements is not necessarily limited to only those elements but may include other elements not expressly listed or inherent to such method, process, or device. Also, the term “or” refers to an inclusive “or” and not to an exclusive “or.”

The systems, methods and devices of this disclosure each have several innovative aspects, no single one of which is solely responsible for all desirable attributes disclosed herein. Details of one or more implementations of the subject matter described in this specification are set forth in the description and the accompanying drawings.

1. An integrated circuit for link monitoring a performance across an unretimed interface, comprising:
one or more analog-to-digital converter slices to receive an analog signal in the unretimed interface and output one or more digital samples of the analog signal corresponding to one or more phases, the unretimed interface coupled to a communication medium of a communication link;
one or more slicers to output one or more determined symbols based on the one or more digital samples;
a clock recovery circuit to receive the one or more determined symbols and output a frequency control word to a phase locked loop;
the phase locked loop to output a clock signal to the one or more analog-to-digital converter slices based on the frequency control word; and
a link metrics extraction circuit to output one or more metrics of the communication link based on the one or more digital samples of the analog signal.

2. The integrated circuit of claim 1, wherein the link metrics extraction circuit comprises:
a signal monitor circuit to generate a signal histogram based on the one or more digital samples of the analog signal.

3. The integrated circuit of claim 1, wherein the link metrics extraction circuit comprises:
an impulse response circuit to generate an impulse response of the communication link based on the one or more digital samples of the analog signal and one or more expected digital samples of the analog signal.

4. The integrated circuit of claim 3, further comprising:
a pseudorandom sequence generator to generate the one or more expected digital samples of the analog signal.

5. The integrated circuit of claim 3, wherein:
the one or more analog-to-digital converter slices comprise an analog-to-digital converter slice having a programmable phase;
the one or more phases correspond to a plurality of phases; and
the one or more expected digital samples of the analog signal are based on the one or more determined symbols output by a slicer of the one or more slicers.

6. The integrated circuit of claim 1, further comprising:
a programmable gain stage to receive the one or more digital samples of the analog signal and output one or more adjusted digital samples;
a least means square circuit to receive an adjusted digital sample of the one or more adjusted digital samples and a determined symbol of the one or more determined symbols and to control the programmable gain stage;
a slicer of the one or more slicers generates the determined symbol of the one or more determined symbols using a plurality of thresholds; and
the one or more slicers to receive the one or more adjusted digital samples.

7. The integrated circuit of claim 1, wherein:
the one or more analog-to-digital converter slices comprise three analog-to-digital converter slices; and
the one or more phases correspond to three consecutive phases.

8. The integrated circuit of claim 1, wherein:
the one or more analog-to-digital converter slices comprise two analog-to-digital converter slices; and
the one or more phases correspond to two consecutive phases.

9. The integrated circuit of claim 1, wherein:
the one or more analog-to-digital converter slices comprise a single analog-to-digital converter slice;
the integrated circuit further includes a pseudorandom sequence generator to receive a determined symbol of the one or more determined symbols and output one or more further determined symbols; and
the clock recovery circuit receives the one or more further determined symbols.

10. The integrated circuit of claim 1, wherein:
the clock recovery circuit comprises a circuit configured to select and output a selected timing error from one or more timing errors;
the clock signal output by the phase locked loop has a clock frequency that is a rational fraction of a Baud Rate of the communication link; and
the one or more phases correspond to fractional phases within a unit interval.

11. The integrated circuit of claim 10, wherein:
the link metrics extraction circuit comprises an oversampled impulse response circuit to generate an oversampled impulse response of the communication link based on the one or more digital samples of the analog signal and one or more expected digital samples of the analog signal; and
the integrated circuit further includes a pseudorandom sequence generator to generate the one or more expected digital samples based on a predetermined periodic signal being sampled at the rational fraction of the Baud Rate.

12. The integrated circuit of claim 1, further comprising:
a pseudorandom sequence generator to generate a previous expected digital sample;
a least means square circuit to receive an error signal and output one or more filter coefficients;
a decision feedback equalizer to receive the previous expected digital sample and the one or more filter coefficients and output a correction signal; and
an adder to apply the correction signal to a signal upstream of the one or more slicers.

13. The integrated circuit of claim 1, further comprising:
a sequence detector to receive the one or more determined symbols and output a trigger signal based on detecting that the one or more determined symbols match a predetermined sequence of symbols, wherein the trigger signal triggers the link metrics extraction circuit to extract the one or more metrics of the communication link.

14. The integrated circuit of claim 1, further comprising:
a signal level detector to receive the one or more determined symbols and output a trigger signal based on detecting that the one or more determined symbols meet a predetermined signal level condition, wherein the trigger signal triggers the link metrics extraction circuit to extract the one or more metrics of the communication link.

15. An unretimed optical interface with link monitoring, comprising:
optics circuitry coupled to a communication medium of a communication link;
one or more analog circuits coupled to the optics circuitry; and
a link monitor comprising:
one or more analog-to-digital converter slices to receive an analog signal of the one or more analog circuits and output one or more digital samples of the analog signal corresponding to one or more phases;
one or more slicers to output one or more determined symbols based on the one or more digital samples;
a clock recovery circuit to receive the one or more determined symbols and output a frequency control word to a phase locked loop;
the phase locked loop to output a clock signal to the one or more analog-to-digital converter slices based on the frequency control word; and
a link metrics extraction circuit to output one or more metrics of the communication link based on the one or more digital samples of the analog signal.

16. The unretimed optical interface of claim 15, wherein:
the one or more analog circuits include one or more of a programmable gain amplifier, an equalizer, a transimpedance amplifier, and a transconductance amplifier; and
the analog signal of the one or more analog circuits is an input to a selected one of the one or more analog circuits or an output of the selected one of the one or more analog circuits.

17. A method for link monitoring in an unretimed interface coupled to a communication medium of a communication link, comprising:
generating, by one or more analog-to-digital converter slices, one or more digital samples of an analog signal in the unretimed interface, the one or more digital samples corresponding to one or more phases;
determining one or more determined symbols based on the one or more digital samples;
generating a frequency control word to a phase locked loop based on the one or more determined symbols;
generating, by a phase locked loop, a clock signal to the one or more analog-to-digital converter slices based on the frequency control word; and
extracting one or more metrics of the communication link based on the one or more digital samples of the analog signal.

18. The method of claim 17, wherein extracting the one or more metrics comprises:
generating a signal histogram based on the one or more digital samples of the analog signal.

19. The method of claim 17, wherein extracting the one or more metrics comprises:
generating an impulse response of the communication link based on the one or more digital samples of the analog signal and one or more expected digital samples of the analog signal.

20. The method of claim 17, wherein extracting the one or more metrics comprises:
triggering the extracting of the one or more metrics based on detecting one or more of: that the one or more determined symbols match a predetermined sequence of symbols, and that the one or more determined symbols meet a predetermined signal level condition.
